(19) United States
(12) Patent Application Publication
(10) Pub. No.: US 2023/0389426 A1
(43) Pub. Date: Nov. 30, 2023

(54) MEMS THERMOELECTRIC GENERATOR, MANUFACTURING PROCESS OF THE GENERATOR AND HEATING SYSTEM COMPRISING THE GENERATOR

(71) Applicant: STMicroelectronics S.r.l., Agrate Brianza (IT)

(72) Inventors: Paolo FERRARI, Gallarate (IT); Flavio Francesco VILLA, Milano (IT); Marco DEL SARTO, Monza (IT)

(73) Assignee: STMicroelectronics S.r.l., Agrate Brianza (IT)

(21) Appl. No.: 18/318,612

(22) Filed: May 16, 2023

(30) Foreign Application Priority Data
May 26, 2022 (IT) 102022000011045

(51) Int. Cl. H10N 10/17; H10N 10/01; H10N 10/82

(52) U.S. Cl. CPC H10N 10/17; H10N 10/01; H10N 10/82

(57) ABSTRACT

MEMS thermoelectric generator comprising: a thermoelectric cell including one or more thermoelectric elements partially extending on a cavity of the thermoelectric cell; a thermoplastic layer extending on the thermoelectric cell and having a top surface and a bottom surface opposite to each other along a first axis, the bottom surface facing the thermoelectric cell and the thermoplastic layer being of thermally insulating material and configured to be processed through laser direct structuring, LDS, technique; a heat sink configured to exchange heat with the thermoelectric cell interposed, along the first axis, between the heat sink and the thermoplastic layer; and a thermal via of metal material, extending through the thermoplastic layer from the top surface to the bottom surface so that it is superimposed, along the first axis, on the cavity, wherein the thermoelectric cell may exchange heat with a thermal source through the thermal via.

### BACKGROUND

### Technical Field

The present disclosure relates to a MEMS thermoelectric generator. Furthermore, it relates to a manufacturing process of the generator and to a heating system comprising the generator. In particular, the thermoelectric generator is of MEMS type and comprises at least one thermoelectric cell and one thermoplastic layer which extends on the thermoelectric cell; a thermal via extends through the thermoplastic layer and allows the propagation of heat, coming from an (external) thermal source couplable to the MEMS thermoelectric generator, towards one part of the thermoelectric cell. This allows a thermal drop between opposite ends of one or more thermoelectric elements comprised in the thermoelectric cell to be increased.

### Description of the Related Art

As known, the direct conversion of thermal energy into electrical power by Seebeck effect is a promising approach for the collection of energy from heat sources (thermal sources). This is particularly useful in the MEMS (“Micro Electro-Mechanical Systems”) field when dealing with small temperature gradients (e.g., smaller than a few tens of ° C., for example equal to about 40° C.) that, precisely in view of the small dimensions, would not be possible to exploit in any other way (e.g., residual heat from industrial plants, residual heat from car engines, low-temperature thermal sources).

The MEMS thermoelectric generators are MEMS devices for exploiting residual heat, coming from thermal sources, which are used for example in the actuators of heater valves without batteries or in torches (in the latter case, exploiting the temperature difference between the human body temperature and the environmental temperature).

In general, thermoelectric generators use thermoelectric materials capable of generating electrical power from the heat received, providing a potential difference (and therefore a current) from a temperature difference (thermal drop) across the generator.

Typically, thermoelectric materials have a low electrical resistivity (ρ, e.g., lower than about 1 mΩ·cm) and a low thermal conductivity (κ, e.g., lower than about 25 W·m⁻¹·K⁻¹). The low thermal conductivity ensures a high temperature difference between the end of the material being heated and the opposite end of the material, even in case of a thermal source that generates a small amount of heat. Furthermore, the voltage difference generated between these ends of the thermoelectric material is directly proportional to the relative temperature difference. Consequently, the low thermal conductivity ensures high voltage differences even from thermal sources that generate a small amount of heat.

Tellurium-based thermoelectric generators are known which use Tellurium-based materials as thermoelectric materials.

Tellurium compounds, such as Bismuth Telluride (Bi₂Te₃), have good Seebeck coefficients (the Seebeck coefficient of a material, also known as thermal power, thermoelectric power, thermoelectric sensitivity, is a measure of the magnitude of the thermoelectric voltage induced by Seebeck effect in response to a temperature difference across this material), high electrical conductivities and low thermal conductivities (e.g., the thermal conductivity of Bismuth Telluride is about 2 W·m⁻¹·K⁻¹). These properties make Bismuth Telluride suitable for being used to form the “thermoelectrically active elements” of a thermoelectric generator (by “thermoelectrically active elements” or “active elements” it is intended the thermoelectric elements of thermoelectric material that are capable of converting a temperature gradient into an electric potential by Seebeck effect).

A conventional Tellurium-based thermoelectric generator comprises a plurality of N-doped Bismuth Telluride active elements and P-doped Bismuth Telluride active elements interconnected between a pair of opposite ceramic substrates provided with metal (Cu or Au) contact regions and conductive lines that interconnect the N-doped and P-doped Bismuth Telluride active elements to each other. The active elements are formed as discrete elements, typically by a process that provides for forming ingots from powdered material and, subsequently, dicing the ingots to form pellets, that define the active elements when inserted between the two ceramic substrates (e.g., in a manual or semi-automatic assembly step).

Conventional Tellurium-based thermoelectric generators are therefore discrete components and thus bulky and non-scalable. More in detail, Bismuth Telluride is not suitable for being used as a material in standard manufacturing processes of integrated circuits (IC), which instead are based on Silicon; in fact, although solutions which integrate Bismuth Telluride in MEMS devices are known, these solutions are not feasible in the practice on a large scale due to the lack of standardized manufacturing processes in MEMS technology that use Bismuth Telluride. Furthermore, Tellurium is a rather rare element, expensive and with a strong environmental impact, and this intrinsically limits its widespread use.

Silicon-based MEMS thermoelectric generators are also known, wherein materials based on Silicon (N-doped and P-doped so that it exhibits Seebeck coefficients different from each other) are used as thermoelectric materials to form the active elements. The silicon-based thermoelectric generators, manufactured with Silicon-compatible MEMS technologies, generally have a heat flow that is transverse or orthogonal to the substrate (“out-of-plane” heat flow) and comprise a plurality of thermoelectric cells with N-P-doped active elements which have a main extension direction transverse or orthogonal to the substrate and which are arranged in such a way that the thermoelectric cells are thermally in parallel and electrically in series and/or in parallel with each other. This ensures the maintenance of a temperature difference high enough to allow the correct operation of these thermoelectric generators, but at the same time it makes the latter bulky (e.g., the thickness of the active elements along the main extension direction is in the order of tens of μm). Furthermore, the electrical powers generated by these thermoelectric generators are generally in the order of magnitude of hundreds of μW, while some applications require higher electrical powers and for example in the order of magnitude of mW.

### BRIEF SUMMARY

Provided is a MEMS thermoelectric generator, a manufacturing process of the generator and a heating system comprising the generator.

A Micro Electro-Mechanical Systems (MEMS) thermoelectric generator comprising at least one thermoelectric cell including a substrate of semiconductor material having a cavity between a first surface of the substrate and a second surface of the substrate opposite to each other along a first direction, an electrically insulating layer on the first surface of the substrate and over the cavity, and one or more thermoelectric elements in the electrically insulating layer, each thermoelectric element of the one or more thermoelectric elements having a first end and a second end opposite to each other along a second direction transverse to the first direction and being configured to convert a thermal drop between the first and the second ends into an electrical potential between the first and the second ends by Seebeck effect, the first end of each thermoelectric element over the cavity and the second end of each thermoelectric element over the substrate.

The MEMS thermoelectric generator further comprising a thermoplastic layer extending on the at least one thermoelectric cell, the thermoplastic layer being of thermally insulating material and configured to be processed by laser direct structuring, lds, technique, a heat sink coupled to a first end of the at least one thermoelectric cell and configured to exchange heat with the thermoelectric cell, the heat sink opposite a first surface of the thermoplastic layer, and a thermal via of metal material extending through the thermoplastic layer from the electrically insulating layer to the first surface of the thermoplastic layer, the thermal via over the first end of each thermoelectric element, wherein the MEMS thermoelectric generator is couplable to a thermal source with the first surface of the thermoplastic layer facing the thermal source and the at least one thermoelectric cell exchanging heat, through the thermal via, with the thermal source to generate the thermal drop between the first and the second ends of each thermoelectric element.

### BRIEF DESCRIPTION OF THE SEVERAL VIEWS OF THE DRAWINGS

For a better understanding of the present disclosure, a preferred embodiment is now described, purely by way of non-limiting example, wherein:

FIG. 1 shows a cross-section of an embodiment of a MEMS thermoelectric generator;

FIG. 2 shows a top view with parts removed of a thermoelectric cell of the MEMS thermoelectric generator of FIG. 1, according to an embodiment;

FIG. 3 shows a cross-section of the thermoelectric cell of FIG. 2;

FIG. 4 shows a further cross-section of the MEMS thermoelectric generator of FIG. 1;

FIGS. 5A-5H show, in cross-section, respective manufacturing steps of the thermoelectric cell of FIG. 2, according to an embodiment;

FIGS. 6A-6D show, in cross-section, respective manufacturing steps of the MEMS thermoelectric generator of FIG. 1, according to an embodiment;

FIG. 7 shows a cross-section of a different embodiment of the MEMS thermoelectric generator;

FIG. 8 shows a perspective view of the MEMS thermoelectric generator of FIG. 7;

FIGS. 9 and 10 show cross-sections of respective and further embodiments of the MEMS thermoelectric generator;

FIGS. 11A-11B show, in cross-section, respective manufacturing steps of the MEMS thermoelectric generator of FIG. 10, according to an embodiment;

FIG. 12 is a schematic view of a heating system comprising the MEMS thermoelectric generator;

FIG. 13 shows a cross-section of a different embodiment of the thermoelectric cell;

FIG. 14 shows a top view with parts removed of the thermoelectric cell of FIG. 13.

In particular, the Figures are shown with reference to a triaxial Cartesian system defined by an X axis, a Y axis and a Z axis, transverse to each other, more specifically, orthogonal to each other.

### DETAILED DESCRIPTION

In the following description, elements common to the different embodiments have been indicated with the same reference numbers.

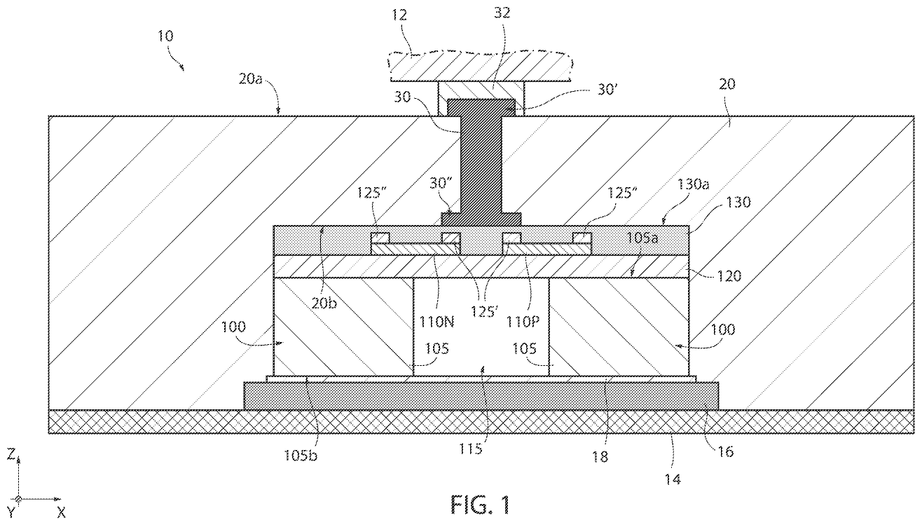

FIG. 1 shows an embodiment of a MEMS thermoelectric generator 10 couplable, in use, to a thermal source 12 so that it exchanges heat with the latter by conduction, in order to generate electrical power from the heat received by the latter. In particular, the MEMS thermoelectric generator 10 is shown in FIG. 1 in cross-section in an XZ plane defined by the X and Z axes.

The MEMS thermoelectric generator 10 (more simply also referred to as generator 10 hereinafter) comprises one or more thermoelectric cells 100. FIG. 1 shows exemplarily a single thermoelectric cell 100, however it is evident that there may similarly be a plurality of thermoelectric cells 100. In case of more thermoelectric cells 100, they are arranged so that they are thermally in parallel and electrically in series and/or in parallel with each other (the combination of the arrangements in series and parallel occurs for example when there are more groups of thermoelectric cells 100 in parallel with each other, each group comprising thermoelectric cells 100 in series with each other).

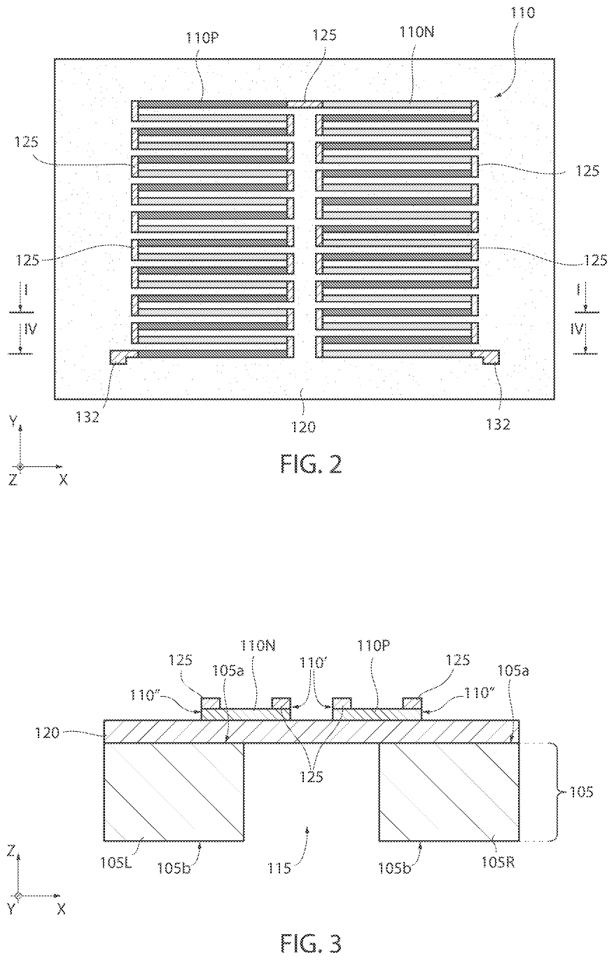

The thermoelectric cell 100 is described in greater detail with reference to FIGS. 2 and 3 which respectively show a top view (in an XY plane defined by the X and Y axes) and a cross-sectional view (in the XZ plane) of an embodiment of the thermoelectric cell 100. In particular, FIG. 3 shows the thermoelectric cell 100 along section line I-I illustrated in FIG. 2.

In detail, the thermoelectric cell 100 comprises a substrate 105 of semiconductor material such as silicon. The substrate 105 has a first surface 105a and a second surface 105b opposite to each other along the Z axis.

A cavity 115 extends through the substrate 105, from the first to the second surface 105a, 105b. In the section of FIG. 3, the cavity 115 is laterally delimited (i.e., along the X axis) by a first and a second portion 105L and 105R of the substrate 105. In other words, the cavity 115 extends along the X axis between the first and the second portions 105L and 105R.

The thermoelectric cell 100 comprises, on the first surface 105A of the substrate 105, a bottom electrically insulating layer 120, for example of electrically insulating material such as oxide (e.g., silicon oxide). The bottom electrically insulating layer 120 also extends on the cavity 115, so that it is suspended thereon.

The thermoelectric cell 100 further comprises one or more thermoelectric elements 110, configured to convert a thermal drop thereacross into an electric potential by Seebeck effect. The thermoelectric elements 110 are of thermoelectric material, in detail of polysilicon (poly-Si) or polysilicon-germanium (poly-SiGe). The thermoelectric elements 110 extend on the bottom electrically insulating layer 120.

In detail, the thermoelectric elements 110 comprise a plurality of interconnected thermoelectric microstructures. Each thermoelectric microstructure has a main extension direction which is transverse or orthogonal to the Z axis and is herein exemplarily considered to be parallel to the X axis. In particular, the thermoelectric microstructures comprise a plurality of thermoelectric microstructures having an N-type conductivity, hereinafter referred to as N-type thermoelectric microstructures 110N, and a plurality of thermoelectric microstructures having a P-type conductivity, hereinafter referred to as P-type thermoelectric microstructures 110P. In greater detail, the N-type thermoelectric microstructures 110N are N-doped (e.g., with phosphorus) poly-Si (or poly-SiGe) thermoelectric microstructures, and the P-type thermoelectric microstructures 110P are P-doped (e.g., with boron) poly-Si (or poly-SiGe) thermoelectric microstructures. In detail, the thermoelectric microstructures 110N,110P exhibit a thermal conductivity comprised between about 5 W·m⁻¹·K⁻¹ and about 25 W·m⁻¹·K⁻¹.

As may be better appreciated in FIG. 2, the N-type thermoelectric microstructures 110N and the P-type thermoelectric microstructures 110P are electrically connected in series to each other in an alternated manner through respective electrically conductive elements 125 (e.g., of metal material such as Al, Ag, Au or Cu); in other words, each N-type thermoelectric microstructure 110N is electrically connected in series to a subsequent P-type thermoelectric microstructure 110P through a respective electrically conductive element 125 and to a respective preceding P-type thermoelectric microstructure 110P through a respective and further electrically conductive element 125. In particular, the N-type thermoelectric microstructures 110N and the P-type thermoelectric microstructures 110P are alternated to each other along the Y axis and each of them has a main extension direction parallel to the X axis. Each thermoelectric microstructure 110N and 110P has a first end 110′ and a second end 110″ opposite to each other along the respective main extension direction (i.e., opposite to each other along the X axis). Each end 110′ and 110″ is in electrical contact with a respective electrically conductive element 125; for example, the electrically conductive element 125 extends on the respective first or second end 110′, 110″. Furthermore, in use, the ends 110′ and 110″ are at different temperatures so that a temperature difference exists therebetween (in detail, T′>T″ with T′ being the temperature of the first end 110′ and T″ being the temperature of the second end 110″). Consequently, the heat flow through the thermoelectric microstructures 110N and 110P is of planar type (i.e., it is transverse or orthogonal to the Z axis).

Furthermore, each N-type thermoelectric microstructure 110N and P-type thermoelectric microstructure 110P is in part vertically superimposed (i.e., along the Z axis) on the substrate 105 and in part vertically superimposed on the cavity 115. In detail, the first end 110′ of each thermoelectric microstructure 110N, 110P is vertically superimposed on the cavity 115 and the second end 110″ of each thermoelectric microstructure 110N, 110P is vertically superimposed on the substrate 105. This ensures the temperature difference between the ends 110′ and 110″. In fact, inside the cavity 115, air or a vacuum is present, which have much lower thermal conductivity, such as 500 to 1000 (for example, 700) times lower than the thermal conductivity of the substrate 105. Consequently, the heat generated by the thermal source 12 and provided to the thermoelectric cell 100 at the first ends 110′ (as better described hereinbelow) mainly radiates through the thermoelectric microstructures 110N, 110P (with higher thermal conductivity than the bottom electrically insulating layer 120) and then through the substrate 105 towards the second surface 105b. In other words, the cavity 115 thermally operates as an open circuit which prevents the heat from radiating from the first ends 110′ directly to the substrate 105 through the bottom electrically insulating layer 120 (i.e., in a substantially vertical manner along the Z axis and therefore with an out-of-plane heat flow), and instead forces the heat to be transmitted through the entire length of the thermoelectric microstructures 110N, 110P before reaching the substrate 105 (i.e., substantially along the X axis at the thermoelectric microstructures 110N, 110P and the bottom electrically insulating layer 120, and therefore with an in-plane heat flow).

For example, the N-type thermoelectric microstructures 110N and the P-type thermoelectric microstructures 110P are formed on the bottom electrically insulating layer 120 according to a planar serpentine arrangement: an example of such an arrangement is described in M. Tomita et al. “10 μW/cm2-Class High Power Density Planar Si-Nanowire Thermoelectric Energy Harvester Compatible with CMOS-VLSI Technology.” In detail, the thermoelectric microstructures 110N and 110P may comprise at least two groups of thermoelectric microstructures, each group comprising N-type thermoelectric microstructures 110N and P-type thermoelectric microstructures 110P serpentine arranged and alternated to each other along the Y axis and the groups being arranged laterally to each other along the X axis to form a single serpentine arrangement and in such a way that the ends facing each other of the thermoelectric microstructures 110N and 110P of different groups are at the same temperature in use (in the example of FIGS. 2 and 3, the first ends 110′ of the thermoelectric microstructures 110N and 110P of the two groups shown face each other).

Since the N-type thermoelectric microstructures 110N and the P-type thermoelectric microstructures 110P have opposite types of electrical conductivity, they also have opposite Seebeck coefficients: when the thermal source 12 is coupled to the thermoelectric cell 100 as better described below, a temperature gradient (thermal drop) is established between the ends 110′ and 110″ of the thermoelectric microstructures 110N, 110P (in fact, the thermoelectric microstructures 110N, 110P are placed between the thermal source 12 and the substrate 105, which in turn is coupled to a heat sink as better described below), which generates by Seebeck effect a respective electric potential difference (voltage difference or voltage drop) between the ends 110′ and 110″ of each thermoelectric microstructure 110N, 110P and therefore, in view of the serpentine arrangement, induces a total potential difference between electrically conductive terminals 132 placed at the ends of the serpentine arrangement (the total potential difference being equal to the sum of the potential differences between the ends 110′ and 110″ of each thermoelectric microstructure 110N, 110P and being due to the flow of charge carriers inside the thermoelectric microstructures 110N, 110P driven by the temperature gradient).

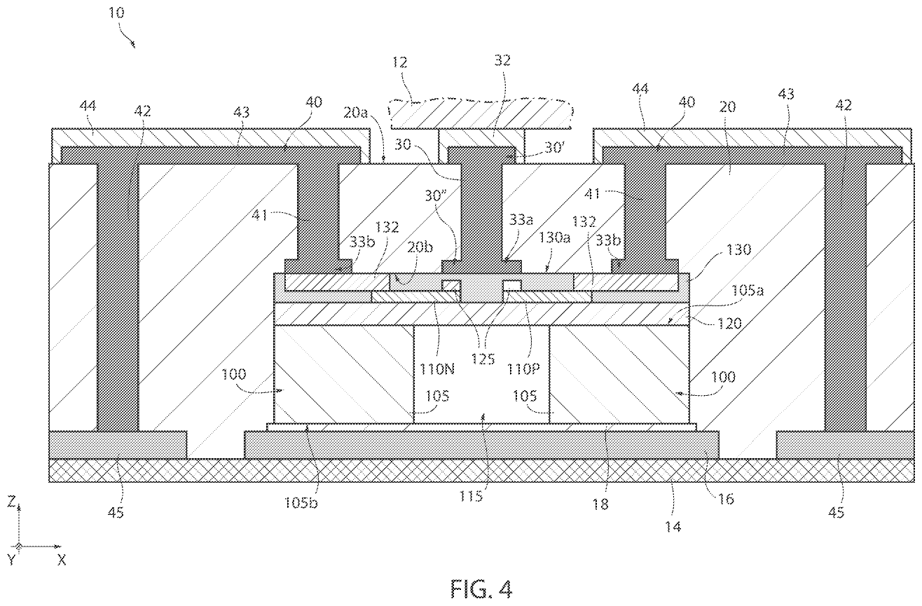

Furthermore, in a manner not shown in FIGS. 2 and 3 but illustrated in FIG. 1, the thermoelectric cell 100 further comprises a top electrically insulating layer 130, for example of insulating material such as oxide (e.g., silicon oxide), which extends on the thermoelectric elements 110 and on the regions of the bottom electrically insulating layer 120 not covered by the thermoelectric elements 110. Furthermore, the top electrically insulating layer 130 extends on the electrically conductive elements 125 in such a way that it covers the electrically conductive elements 125 placed on the first ends 110′ of the thermoelectric microstructures 110N, 110P (hereinafter, first electrically conductive elements 125′) and the electrically conductive elements 125 placed on the second ends 110″ of the thermoelectric microstructures 110N, 110P (hereinafter, second electrically conductive elements 125″), and leaves exposed, at least partially, the electrically conductive terminals 132 (e.g., FIG. 4). In this manner the top electrically insulating layer 130 electrically insulates the thermoelectric microstructures 110N, 110P along the serpentine arrangement but also allows its electrical connection towards the external environment through the electrically conductive terminals 132, as better described below.

More generally, the top electrically insulating layer 130 and the bottom electrically insulating layer 120 form an electrically insulating layer 120, 130 wherein the thermoelectric microstructures 110N, 110P and the electrically conductive elements 125 are buried, and which instead at least partially exposes the electrically conductive terminals 132.

With reference again to FIG. 1, the generator 10 also comprises a heat sink 14 (e.g., a metal plate of thermally conductive material such as aluminum, optionally including fins that increase heat sinking towards the external environment) thermally coupled to the substrate 105. For example, the second surface 105b of the substrate 105 is fixed to a die pad (of a conductive material such as copper) 16, for example through an adhesive layer 18 (e.g., of “Conductive Die Attach Film,” CDAF, type) interposed along the Z axis between the substrate 105 and the die pad 16; furthermore, the die pad 16 is fixed to the heat sink 14 and for example extends on the heat sink 14 so that it is interposed along the Z axis between the latter and the substrate 105. The adhesive layer 18 and the die pad 16 are thermally conductive in such a way that they allow the heat transfer from the substrate 105 to the heat sink 14.

The generator 10 further comprises a thermoplastic layer (or total thermoplastic layer) configured to be processed (i.e., treated, manipulated) through “Laser Direct Structuring” (LDS) technique, of known type. In the present embodiment, the thermoplastic layer is formed by a first thermoplastic layer, indicated in FIG. 1 with the reference number 20. In particular, the first thermoplastic layer 20 is of thermoplastic polymeric material doped with organic-metal compounds (e.g., chelated complexes of a metal such as palladium, Pd²⁺, or copper, Cu²⁺): when a laser beam radiates the first thermoplastic layer 20, the organic-metal compounds present in the radiated polymeric material are chemically activated in such a way that they become capable of catalyzing the selective precipitation of metal during a subsequent metal deposition step through electroplating, as better described below. Greater details regarding the material of the first thermoplastic layer 20 and the LDS technique may be found in the document “Manufacturing of Molded Interconnect Devices from Prototyping to Mass Production with Laser Direct Structuring,” Heininger et al., 2004. Furthermore, the thermoplastic polymeric material is also chosen so that it has a reduced thermal conductivity, in particular lower than about 1 W·m⁻¹·K⁻¹. For example, the thermoplastic polymeric material may be epoxy resin.

The first thermoplastic layer 20 covers the thermoelectric cell 100 so that it thermally insulates it from the thermal source 12. In particular, the first thermoplastic layer 20 extends on the thermoelectric cell 100 (i.e., on a top surface 130a of the top electrically insulating layer 130, opposite to the bottom electrically insulating layer 120 along the Z axis) and also laterally to the thermoelectric cell 100 and on the exposed regions of the die pad 16 and of the heat sink 14 in such a way that the thermoelectric cell 100 is encapsulated between the first thermoplastic layer 20 and the die pad 16. In greater detail, the first thermoplastic layer 20 has a top surface 20a and a bottom surface 20b opposite to each other along the Z axis, where the bottom surface 20b is in contact with the thermoelectric cell 100, the die pad 16 and the heat sink 14.

A thermal via (or thermal connection, or total thermal via), of conductive material such as metal (e.g., copper), extends through the first thermoplastic layer 20 so that it faces (and optionally protrudes beyond) the top surface 20a and is in contact with the thermoelectric cell 100 at the first ends 110′ of the thermoelectric microstructures 110N, 110P. In the present embodiment, the thermal via is formed by a first thermal via 30. In detail, the first thermal via 30 extends along the Z axis from the top surface 20a to the bottom surface 20b so that it is in contact with the top surface 130a of the top electrically insulating layer 130 and is vertically superimposed (along the Z axis) on the first electrically conductive elements 125′. The first thermal via 30 has a first end 30′ and a second end opposite to each other along the Z axis, the first end 30′ protruding outside the first thermoplastic layer 20 at the top surface 20a (or more generally, facing the top surface 20a) and the second end 30″ being in contact with the top surface 130a of the top electrically insulating layer 130 and being aligned along the Z axis to the first electrically conductive elements 125′. In detail, the second end 30″ extends only on the first ends 110′ and on the region comprised therebetween, so that it forces the heat flow to flow through the thermoelectric microstructures 110N, 110P preventing it from occurring in a substantially vertical manner; in greater detail, the first end 110′ means the portion of the thermoelectric microstructure 110N, 110P which, along the X axis, has a length equal to at most about 20% of the maximum total length of the thermoelectric microstructure 110N, 110P. Since the top electrically insulating layer 130 is interposed along the Z axis between the first thermal via 30 and the first electrically conductive elements 125′, the latter are electrically insulated with respect to the first thermal via 30; however, they exchange heat by conduction with the first thermal via 30, since the top electrically insulating layer 130 is of thermally conductive material (or in any case has a thickness, along the Z axis, such that it creates a reduced thermal resistance, for example lower than about 0.15Ω).

In particular and as better described below, the first thermal via 30 is provided in the first thermoplastic layer 20 through LDS, i.e., by ablation and activation through laser of portions of the first thermoplastic layer 20, followed by electroplating in the active regions.

For exemplary and non-limiting purposes, the first thermal via 30 has a substantially cylindrical or conical shape (therefore with an XY plane section constant from the first to the second end 30′ and 30″ or, respectively, decreasing from the first to the second end 30′ and 30″) or cylindrical/conical shape centrally tapered along the Z axis (as shown in FIG. 1, wherein the ends and 30″ are joined to each other by a central portion integral with the ends 30′ and 30″ and with an XY plane section lower than the XY plane sections of the ends 30′ and 30″). In particular, the second shape ensures greater areas of contact with the thermal source 12 and with the thermoelectric cell 100 while maintaining the section of the central portion of the first thermal via 30 limited, thus optimizing the heat exchange of the first thermal via 30 without compromising its manufacturability through LDS.

Optionally, a thermal coupling layer 32, of conductive material such as metal (e.g., comprising a stack of metal layers which, in succession to each other, include for example Sn-Cu-Ni-Au), externally surrounds the first end 30′ so that it allows the heat exchange between the first thermal via 30 and the external environment (e.g., the thermal source 12) and prevents the oxidation of the first end 30′ of the first thermal via 30.

FIG. 4 shows the generator 10 along section line Iv-Iv illustrated in FIG. 2, placed at the electrically conductive terminals 132.

As may be seen in FIG. 4, each electrically conductive terminal 132 is electrically connected to a respective lead 45 through a respective electrical connection structure 40. The leads and the electrical connection structures 40 are comprised in the generator 10 and are optional. For example, the leads 45 extend on the heat sink 14 (so that they are electrically insulated with respect to the latter, for example through the electrical insulation layer 60 described below), laterally to the die pad 16 and on opposite sides to each other with respect to the die pad 16 along the X axis, so that they are surrounded by the first thermoplastic layer 20 and by the heat sink 14. The leads 45 form, together with the die pad 16, a frame of the generator 10.

In the embodiment of FIG. 4, each electrical connection structure 40 comprises a first electrical via 41, a second electrical via 42 and an electrical connection portion 43 which joins the electrical vias 41 and 42. The first and the second electrical vias 41 and 42 are similar to the first thermal via 30 and therefore are not described again in detail. The first electrical via 41 extends through the first thermoplastic layer 20 from the top surface 20a to the thermoelectric cell 100 so that it is in electrical contact with the respective electrically conductive terminal 132. The second electrical via 42 extends through the first thermoplastic layer 20 from the top surface 20a to the respective lead 45 so that it is in electrical contact with the latter. The electrical connection portion 43 is of the same material as the electrical vias 41 and 42 and extends on the top surface 20a between the electrical vias 41 and 42, so that it electrically contacts the latter to each other. Furthermore, an insulation layer 44, of insulating material such as oxide (e.g., insulating tape, with a thickness, along the Z axis, of a few μm), externally surrounds the electrical connection portion 43 so that it electrically and thermally insulates the electrical connection structure 40 with respect to the external environment. In this manner, a conductive path is created between the electrically conductive terminals 132 and the respective leads 45, thus allowing the potential difference generated by the thermoelectric cell 100 to be transferred to the leads 45.

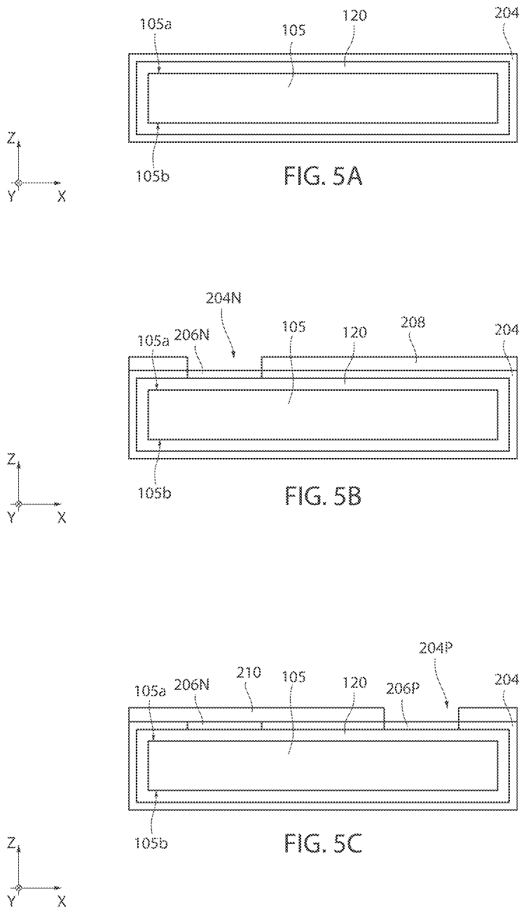

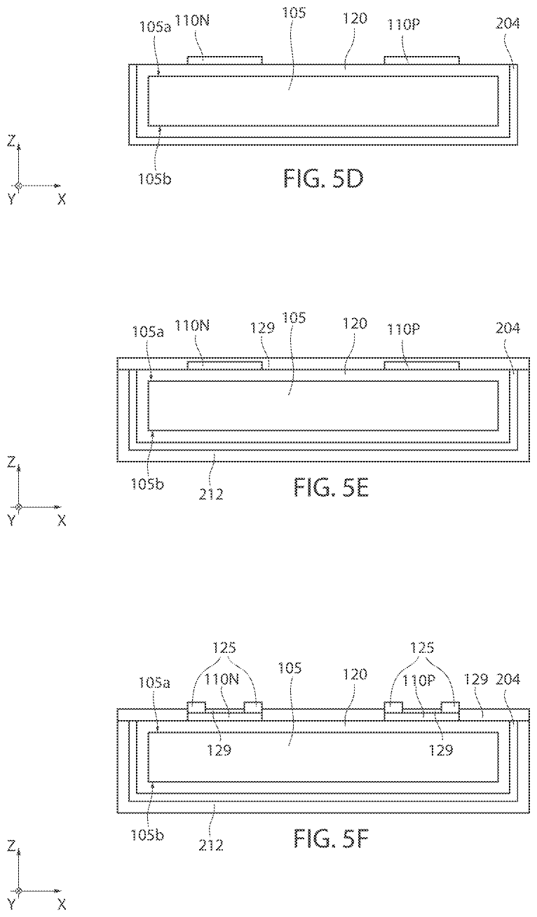

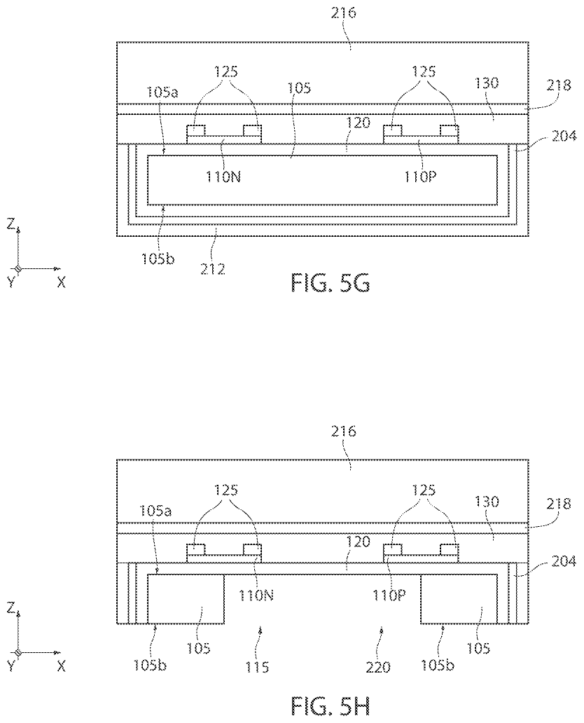

FIGS. 5A-5H show respective steps of a known manufacturing process of the thermoelectric cell 100 of FIGS. 2 and 3. In particular, the manufacturing steps are shown with reference to cross-sections of the thermoelectric cell 100 taken along section line I-I.

In FIG. 5A, a substrate 105 (i.e., a first wafer of semiconductor material, e.g., Si) is arranged and the bottom electrically insulating layer 120 (of electrically insulating material, such as an oxide, e.g., silicon oxide) and a thermoelectric material layer 204, in detail of polysilicon (poly-Si) or polysilicon-germanium (poly-SiGe) for example of intrinsic type, are formed in succession, on an external surface thereof. In particular, the substrate 105 has a first and a second surface 105a and 105b opposite to each other along the Z axis and forming part of the external surface of the substrate 105. In detail, at the first surface 105a, the bottom electrically insulating layer 120 is formed on the substrate 105 (e.g., by thermal oxidation of the substrate 105) and the thermoelectric material layer 204 is formed on the bottom electrically insulating layer 120 (e.g., by deposition). The thermoelectric material layer 204 is intended to form the thermoelectric elements 110.

In FIG. 5B, a first doped portion 206N is provided in the thermoelectric material layer 204, by N-type doping of a first exposed region 204N of the thermoelectric material layer 204. In detail, a first mask 208 is formed on the thermoelectric material layer 204, which covers the thermoelectric material layer 204 so that it leaves the first exposed region 204N exposed; in this first exposed region 204N a selective doping with N-type doping species is performed, in a per se known manner (e.g., by ion implantation); after that, the first mask 208 is removed. The first doped portion 206N is intended to form a respective N-type thermoelectric microstructure 110N.

In FIG. 5C, a second doped portion 206P is provided in the thermoelectric material layer 204, laterally to the first doped portion 206N, by P-type doping of a second exposed region 204P of the thermoelectric material layer 204. In detail, a second mask 210 is formed on the thermoelectric material layer 204, which covers the thermoelectric material layer 204 (in particular, the first doped portion 206N) so that it leaves the second exposed region 204P exposed; in this second exposed region 204P a selective doping with P-type doping species is performed, in a per se known manner (e.g., by ion implantation); after that, the second mask 210 is removed. The second doped portion 206P is intended to form a respective P-type thermoelectric microstructure 110P.

In FIG. 5D, the thermoelectric material layer 204 is removed (e.g., by etching, such as dry etching) so that it exposes the bottom electrically insulating layer 120, leaving instead, on the bottom electrically insulating layer 120, the first and the second doped portions 206N and 206P which therefore define respective N- and P-type thermoelectric microstructures 110N, 110P. For example, this etching is performed through a further mask, not shown, which covers the first doped portion 206N and the second doped portion 206P exposing the rest of the thermoelectric material layer 204.

In FIG. 5E, a protective oxide layer 212 (optional, of oxide such as silicon oxide) is formed on the thermoelectric material layer 204 (e.g., by thermal oxidation of poly-Si or poly-SiGe). Furthermore, a first insulating layer 129 (part of the top electrically insulating layer 130), of insulating material such as BPSG (borophosphosilicate glass), is formed on the thermoelectric material layer 204 and on the N- and P-type thermoelectric microstructures 110N, 110P. For example, this occurs by depositing the insulating material on the thermoelectric material layer 204 and on the N- and P-type thermoelectric microstructures 110N, 110P, followed by reflow of the deposited insulating material.

In FIG. 5F, the electrically conductive elements 125 (and similarly the electrically conductive terminals 132, not visible in the Figure which is taken along section line I-I) are provided on the N- and P-type thermoelectric microstructures 110N, 110P. In particular, an etching of the first insulating layer 129 is performed at the ends 110′ and 110″ of the thermoelectric microstructures 110N, 110P, so that it exposes these ends 110′ and 110″ (for example, this etching is performed through a further mask not shown which is previously formed on the thermoelectric material layer 204 so that it exposes regions of the latter vertically superimposed, along the Z axis, on the ends 110′ and 110″); subsequently, the electrically conductive elements 125 are formed by deposition of metal (e.g., AlCu) at the ends 110′ and 110″ exposed of the thermoelectric microstructures 110N, 110P, so that the electrically conductive elements 125 are in direct electrical and physical contact with the ends 110′ and 110″ of the thermoelectric microstructures 110N, 110P.

In a manner not shown, further deposition steps follow, in succession to each other and on the first insulating layer 129 and on the electrically conductive elements 125, of one or more second insulating layers of electrically insulating material such as tetraethyl orthosilicate (TEOS) and/or of passivating material such as SiN. Together with the first insulating layer 129, these one or more second insulating layers form the top electrically insulating layer 130 which covers the electrically conductive elements 125 and the thermoelectric microstructures 110N, 110P and exposes the electrically conductive terminals 132.

Furthermore, optionally and in a manner not shown, portions of a conductive layer (of metal such as copper, hereinafter referred to as metal contacts) are formed on the top electrically insulating layer 130, laterally to each other along the X axis, intended to form the second ends 30″ of the first thermal via 30 and of the first and second electrical vias 41 and 42 and indicated in FIG. 4 with the references 33a and 33b. In particular, this occurs removing, by etching, the portions of the top electrically insulating layer 130 superimposed on the electrically conductive terminals 132, to form respective recesses (not shown) in the top electrically insulating layer 130 which expose the electrically conductive terminals 132 (this step is absent in case the electrically conductive terminals 132 are already exposed by the top electrically insulating layer 130, as for example shown in FIG. 4), and subsequently depositing the conductive layer both on the region of the top electrically insulating layer 130 vertically superimposed on the first electrically conductive elements 125′, and in the recesses formed in the top electrically insulating layer 130 (or in any case on the first electrically conductive elements 125′ exposed by the top electrically insulating layer 130) and optionally also on the regions of the top electrically insulating layer 130 contiguous to the recesses. The portions of the conductive layer (metal contacts) 33a and 33b thus provided are physically and electrically separated from each other. The metal contact 33a superimposed on the first electrically conductive elements 125′ forms the second end 30″ of the first thermal via 30 and is electrically decoupled from the first electrically conductive elements 125′ owing to the top electrically insulating layer 130, while the metal contacts 33b superimposed on the electrically conductive terminals 132 form the second ends of the electrical vias 41 and are electrically coupled to the electrically conductive terminals 132 through the recesses in the top electrically insulating layer 130 (consequently, these metal contacts 33b form conductive vias through the top electrically insulating layer 130).

The steps of FIGS. 5A-5F lead to form the thermoelectric cell 100, wherein however the substrate 105 does not yet have the cavity 115.

In FIG. 5G, a second wafer (or transport wafer) 216 of semiconductor material (e.g., Si) is temporarily coupled (in detail, fixed) to the thermoelectric cell 100 so that it faces the top electrically insulating layer 130. For example, the second wafer 216 is glued to the thermoelectric cell 100 through known wafer bonding techniques, e.g., through a bonding adhesive layer 218 interposed between the second wafer 216 and the top electrically insulating layer 130.

In FIG. 5H, the thermoelectric cell 100, supported by the second wafer 216, is subject to polishing (optional) at the second surface 105b of the substrate 105, in order to expose the second surface 105b by removing the bottom electrically insulating layer 120, protective oxide layer 212, and the thermoelectric material layer 204 and to reduce the thickness of the substrate 105 along the Z axis. Subsequently, an etching is performed, from the second surface 105b and up to reaching the first surface 105a, to form the cavity 115 in the substrate 105. In particular, a further mask, not shown, is formed on the second surface 105b so that it covers the second surface 105b leaving exposed a relative cavity region 220 where through the etching (e.g., dry etching for example by Bosch etching) is performed which removes the portion of the substrate 105 aligned along the Z axis with the cavity region 220 of the second surface 105b, exposed by the mask, thus forming the cavity 115 which separates the first and the second portions 105L and 105R of the substrate 105 from each other along the X axis. In detail, the cavity region 220 is aligned, along the Z axis, with the first ends 110′ of the thermoelectric microstructures 110.

Subsequently, the second wafer 216 and the bonding adhesive layer 218 are removed to obtain the thermoelectric cell of FIG. 3.

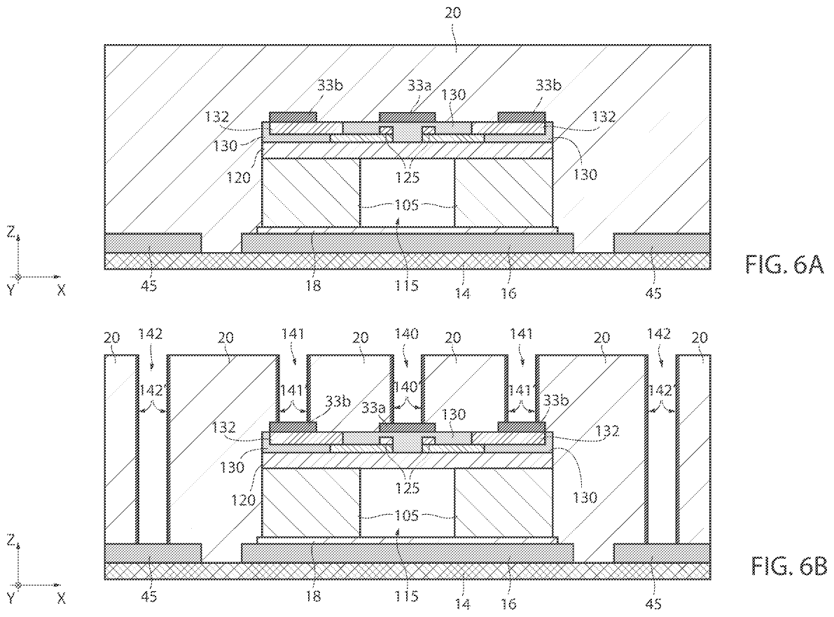

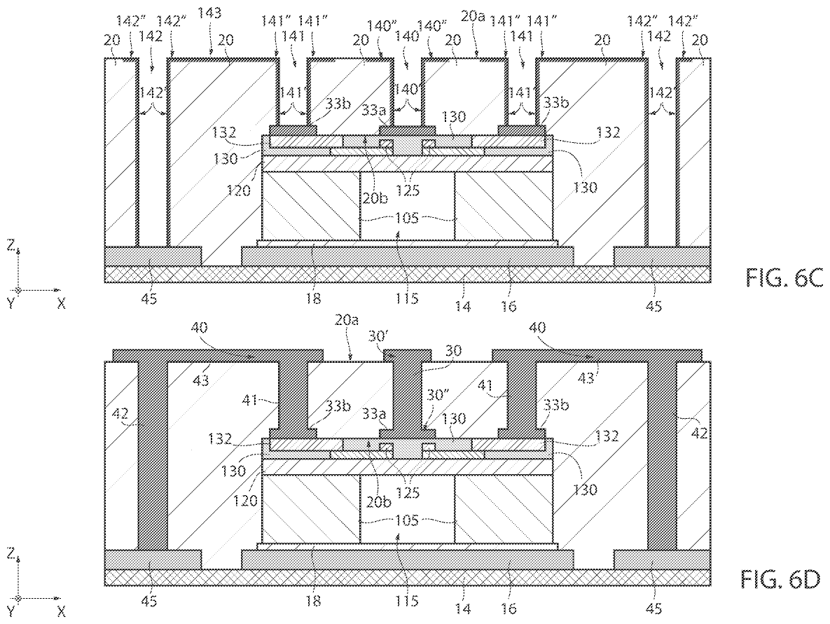

FIGS. 6A-6D show respective steps of the manufacturing process of the generator 10 of FIGS. 1 and 4. In particular, the manufacturing steps are shown with reference to cross-sections of the generator 10 taken along section line Iv-Iv and refer to back-end manufacturing steps of the generator 10.

FIG. 6A shows the thermoelectric cell 100 provided according to the steps discussed with reference to FIGS. 5A-5H. Also shown are the metal contacts 33a and 33b, absent in FIGS. 5A-5H. With reference to FIG. 6A, the thermoelectric cell 100 is fixed to the die pad 16 through the adhesive layer 18. Furthermore, the die pad 16 and the leads 45 are fixed to the heat sink 14, for example through known die attach techniques. Furthermore, the first thermoplastic layer 20 is formed on the thermoelectric cell 100 and on the leads 45. In particular, the first thermoplastic layer 20 is formed by injection molding so that it covers the thermoelectric cell 100, the leads 45 and the heat sink 14 (in detail, so that it extends also between the leads 45 and the thermoelectric cell 100).

In FIG. 6B, a first trench 140 vertically superimposed on the metal contact 33a and on the cavity 115, second trenches 141 (optional) vertically superimposed on the respective metal contacts 33b and on the respective electrically conductive terminals 132, and third trenches 142 (optional) vertically superimposed on the respective leads 45 are provided in the first thermoplastic layer 20.

Consequently, the trenches 140-142 are arranged laterally to each other and extend from the top surface 20a up to reaching the bottom surface 20b, thus exposing respectively the metal contact 33a, the metal contacts 33b and the leads 45. The trenches 140-142 are provided by LDS technique, i.e., by a laser beam that generates photochemical ablation and vaporization of the radiated polymeric material. In detail, the laser beam impinges on respective trench regions of the top surface 20a of the first thermoplastic layer 20, causing the ablation and the vaporization of the polymeric material in these trench regions and consequently forming the trenches 140-142. The trench regions are therefore vertically superimposed respectively on the metal contact 33a (more generally, on the cavity 115), on the metal contacts 33b and on the leads 45. For example, the laser beam may be generated with a neodymium-doped yttrium aluminum garnet (Nd:YAG) laser (e.g., with a wavelength λ of about 1064 nm). In addition to the selective removal of the radiated polymeric material, the laser beam also chemically activates the organic-metal compounds comprised in the polymeric material which is radiated without being removed. In greater detail, when the polymeric material is radiated for a longer time than a threshold time (depending in a per se known manner on factors such as the chosen polymeric material and the wavelength of the laser beam), it is vaporized and detaches from the first thermoplastic layer 20; on the other hand, when it is radiated for a shorter time than the threshold time, the polymeric material does not detach from the first thermoplastic layer 20 and the organic-metal compounds comprised therein are chemically modified so that they become selective catalysts of metal precipitation. For this reason, side walls 140′, 141′, 142′ of the trenches 140, 141, 142 are chemically activated by the laser beam during the formation of the trenches 140, 141, 142. Greater details regarding the LDS technique may be found in the document “Manufacturing of Molded Interconnect Devices from Prototyping to Mass Production with Laser Direct Structuring,” Heininger et al., 2004.

In FIG. 6C, some regions of the top surface 20a of the first thermoplastic layer 20, intended to house the first ends 30′ of the first thermal via 30 and of the electrical vias 41 and 42 and the electrical connection portions 43, are also optionally chemically activated by radiation with the laser beam. In particular, there are illuminated and activated: a first activated region 140″ (optional) of the top surface 20a, which surrounds the opening of the first trench 140 and is intended to house the first end 30′ of the first thermal via 30; second activated regions 141″ (optional) of the top surface which surround the openings of the respective second trenches 141 and are intended to house the first ends 30′ of the first electrical vias 41; third activated regions 142″ (optional) of the top surface 20a, which surround the openings of the respective third trenches 142 and are intended to house the first ends 30′ of the second electrical vias 42; fourth activated regions 143 of the top surface 20a, which extend along the X axis between the respective second and third activated regions 142′ and 142″ (more generally, between the respective second and third trenches 141 and 142) and are intended to house the electrical connection portions 43.

In FIG. 6D, a metal deposition step is performed (in detail, by electroplating) to form the vias 30, 41, 42 and the electrical connection portions 43. In particular, metal (e.g., Cu) is deposited in the trenches 140-142 and on the top surface 20a of the first thermoplastic layer 20. The metal deposition adheres to the first thermoplastic layer 20 where the latter has been chemically activated by the laser beam so that it catalyzes the metal precipitation. Consequently, the metal is deposited in the trenches 140-142 (up to reaching and electrically and physically contacting the metal contacts 33a and 33b and the leads 45) and on the activated regions 140″-142″, 143. The generator 10 having the first thermal via 30 and the electrical connection structures 40 provided in the first thermoplastic layer 20 therefore defines a molded interconnect device (MID).

Then, in an optional and not-shown manner, the formation of the thermal coupling layer 32 follows on the first end 30′ of the first thermal via 30. In particular, this occurs by galvanically growing one or more metal layers (e.g., Sn-Cu-Ni-Au, in succession to each other) on the first end of the first thermal via 30 (of conductive material such as copper).

Furthermore, again in an optional and not-shown manner, the formation of the insulation layer 44 is performed on the electrical connection portions 43. In particular, this occurs by gluing insulating tape on the electrical connection portions 43. With the previously described steps the structure of the generator 10 shown in FIG. 4 is obtained.

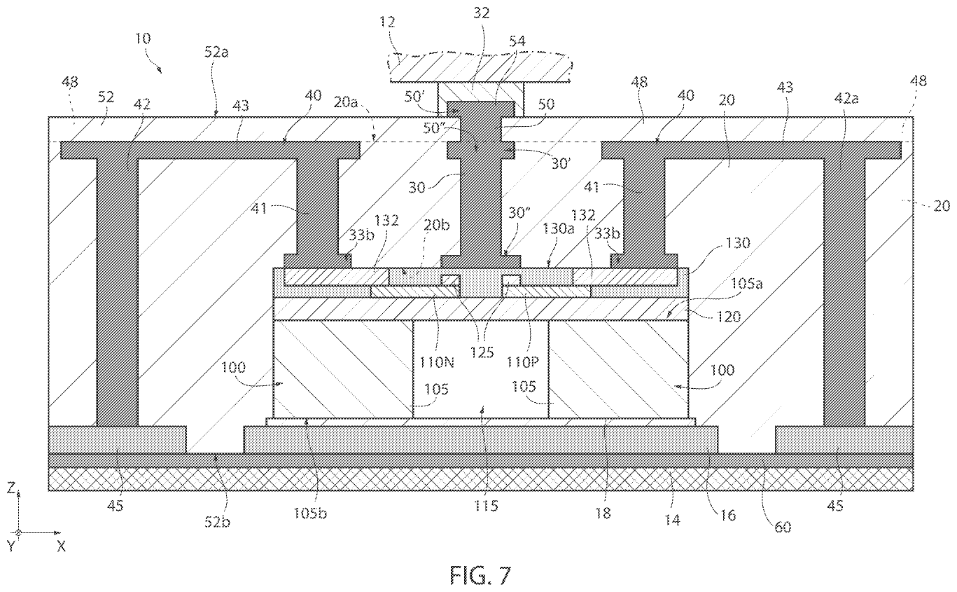

FIG. 7 shows a different embodiment of the generator 10. In particular, the generator 10 of FIG. 7 is similar to that of FIG. 4 and therefore is not described again in detail.

However, in the embodiment of FIG. 7 the generator 10 comprises a second thermoplastic layer 48 extending on the first thermoplastic layer 20 previously described and on the electrical connection structures 40. The second thermoplastic layer 48 is similar to the first thermoplastic layer 20 and is integral with the latter. In the present embodiment, the thermoplastic layer (here indicated with the reference 52) is formed by the first thermoplastic layer 20 and by the second thermoplastic layer 48 and has a top surface 52a (facing, in use, the thermal source 12) and a bottom surface 52b (coinciding with the bottom surface 20b of the first thermoplastic layer 20).

Furthermore, the generator 10 of FIG. 7 comprises a second thermal via 50 on the first thermal via 30. In the present embodiment, the thermal via is formed by the first and the second thermal vias 30, 50 and is also indicated with the reference number 54. The second thermal via 50, similar to the first thermal via 30, is vertically superimposed on the first thermal via 30 and is in direct physical contact with the latter. In particular, the first end 30′ of the first thermal via 30 functions as the second end 50″ of the second thermal via 50, while the first end 50′ of the second thermal via 50 faces (optionally protrudes beyond) the top surface 52a. The thermal via 54 traverses the thermoplastic layer 52 from the top surface 52a (first end 50′) up to reaching the top electrically insulating layer 130 of the thermoelectric cell 100 (second end 30″). The thermal source 12 is couplable to the first end 50′ of the second thermal via 50, so that it allows the heat exchange between the thermal source 12 and the thermoelectric cell 100 through the thermal via 54.

In general, in FIG. 7 the electrical connection structures 40 are buried in the thermoplastic layer 52; on the other hand, the first end 50′ of the thermal via 54 extends on the top surface 52a in such a way that it may be in contact with the thermal source 12 to receive heat from the latter. In greater detail, the thermoplastic layer 52 surrounds the electrical connection structures 40 and also extends over the electrical connection portions 43, in particular with a thickness along the Z axis such that it prevents thermal exchange between the electrical connection structures 40 and the external environment. In this manner, the electrical connection structures 40 are thermally insulated with respect to the thermal source 12 by the thermoplastic layer 52. Consequently, the thermal source 12 may be in contact with the thermal via 54 and the top surface 52a to exchange heat with the thermal via 54, while ensuring the thermal insulation of the electrical connection structures 40. Otherwise, in the embodiment of FIG. 4, the thermal and electrical insulation of the electrical connection structures 40 is ensured by the insulation layer 44.

Furthermore, FIG. 7 also shows an electrical insulation layer 60 (optional) interposed along the Z axis between the heat sink 14 and the leads 45. Optionally, the electrical insulation layer 60 is also interposed along the Z axis between the heat sink 14 and the die pad 16. The electrical insulation layer 60 fixes the leads 45 and the die pad 16 to the heat sink 14 and is of electrically but not thermally insulating material (e.g., of silicone-based material, such as thermal interface material, TIM). In this manner, the electrical insulation layer 60 allows the heat exchange between the die pad 16 and the heat sink 14 and electrically decouples both the leads 45 and the die pad 16 with respect to the heat sink 14, thus making the operation of the generator 10 independent of any noise or electrical disturbances induced by the external environment on the heat sink 14. Although the electrical insulation layer 60 is shown with reference to the sole embodiment of FIG. 7, it may similarly be present in the other embodiments of the generator 10.

The generator 10 of FIG. 7 is manufactured using the manufacturing process previously described with reference to FIGS. 5A-5H and 6A-6D. Furthermore, the manufacturing process according to this embodiment comprises, at the end of the formation of the first thermal via 30 and of the electrical connection structures 40 (FIG. 6D, i.e., before the thermal coupling layer 32 and the insulation layer 44 are formed), forming the second thermoplastic layer 48 on the first thermoplastic layer 20 previously formed, on the first thermal via 30 and on the electrical connection structures 40. The formation of the second thermoplastic layer 48 occurs similarly to what has been previously described with reference to FIG. 6A and therefore is not described again in detail.

Following the formation of the second thermoplastic layer 48, steps similar to those described with reference to FIGS. 6B-6D (therefore not described again) follow to form the second thermal via 50 on the first thermal via 30, in such a way that the second thermal via 50 is vertically superimposed on the first thermal via 30 and is in direct physical contact with the latter to form with the latter the thermal via 54 which traverses the thermoplastic layer 52 from the top surface 52a up to reaching the top electrically insulating layer 130 of the thermoelectric cell 100.

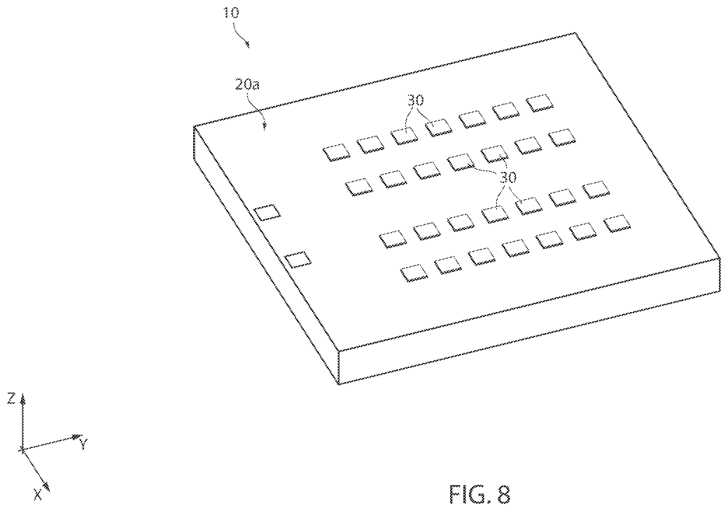

FIG. 8 shows an embodiment of the generator 10 wherein the latter comprises a plurality of thermoelectric cells 100 arranged in a matrix parallel to the XY plane. Each thermoelectric cell 100 is connected to the respective first thermal via 30 (or, similarly, to the respective thermal via 54), visible in FIG. 1 on the top surface 20a in a respective matrix arrangement (for simplicity of display, FIG. 8 does not show the thermal coupling layers 32). As previously described, each thermoelectric cell 100 comprises a respective cavity 115, not shown in FIG. 8 as it is internal to the generator 10 and therefore not visible in the perspective view of FIG. 8.

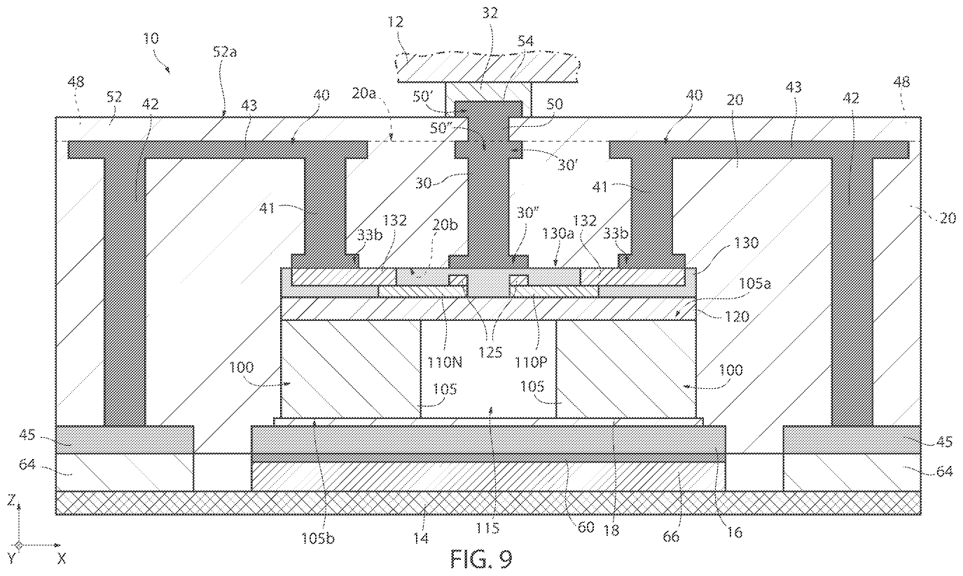

FIG. 9 shows a further embodiment of the generator 10. By way of example, the generator 10 of FIG. 9 is based on the embodiment of FIG. 7; nevertheless, it is evident that the following considerations are similarly applicable also to the other embodiments of the generator 10.

In particular, the generator 10 of FIG. 9 has the leads 45 which extend on one (or on respective) PCB(s) (“printed circuit board”) 64 which in turn extends on the heat sink 14. Furthermore, optionally, a thermal conduction intermediate element 66 (also called “thermal socket”) is present between the heat sink 14 and the die pad 16 (for example, fixed to the latter through the electrical insulation layer 60) to allow the die pad 16 to exchange heat with the heat sink 14. In detail, the thermal conduction intermediate element 66 is of thermally conductive material such as metal, for example aluminum, and has a thickness along the Z axis substantially equal to that of the PCB 64 and in any case such that it allows the die pad 16 to exchange heat with the heat sink 14.

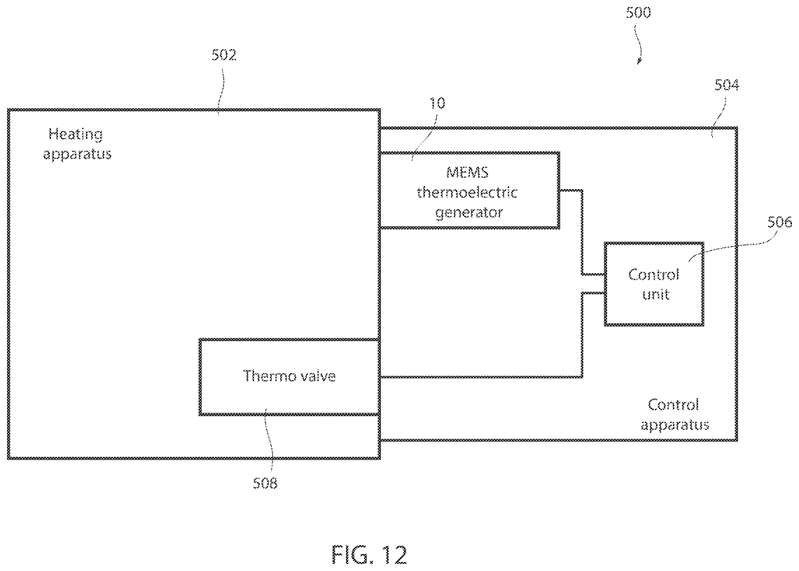

FIG. 12 shows an example of application of the generator 10. In particular, FIG. 12 shows a heating system 500 comprising a heating apparatus 502 (e.g., a radiator such as a home radiator) and a control apparatus 504. The heating apparatus 502 comprises for example a thermo valve 508 which adjusts the level of heat generated by the heating apparatus 502, in a per se known manner. The control apparatus 504 is coupled to the heating apparatus 502 to receive heat from the latter and for example to control its operation (in detail, to control the thermo valve 508 and thus adjust the level of heat generated by the heating apparatus 502). The control apparatus 504 comprises the generator 10 and, for example, a control unit 506 (e.g., CPU or dedicated microprocessor) electrically coupled to each other. In particular, the generator 10 is coupled to the heating apparatus 502 to receive heat from the latter (which operates as a thermal source 12) and for example to generate an electrical power which powers the control unit 506, in turn coupled to the thermo valve 508 to control its operation. Optionally, the control apparatus 504 may further comprise a battery configured to be recharged by the power supply supplied by the generator 10 and to power the control unit 506 and the thermo valve 508. In this manner, the thermo valve 508 is controlled by the control apparatus 504 which is electrically powered autonomously from the heat generated by the heating apparatus 502, and therefore which does not need to be connected to an external power supply.

From an examination of the characteristics of the present disclosure, the advantages that it affords are evident.

In detail, the generator 10 is an integrated device which allows the conversion from thermal energy to electrical power. The generator 10 may be made using MEMS technology at low cost and simply, using materials with reduced environmental impact and that are easy to find.

Furthermore, being an integrated device, the generator 10 occupies a small volume and may generate electrical powers of the order of mW, so it is usable in applications such as the driving of the thermo valves of a radiator.

The generator 10 allows for a heat flow through the thermoelectric microstructures 110N and 110P (of reduced thickness, e.g., equal to a few thousand angstroms, for example up to 1-2 μm) which is of planar type and therefore provides a substantially planar (horizontal) thermoelectric generation structure. This makes the generator 10 more competitive from the industrial point of view (with reduced production cost), simpler from the point of view of manufacture and more mechanically stable.

Furthermore, these high temperature gradients (e.g., temperature differences through the thermoelectric microstructures 110N and 110P of a few tens of ° C., e.g., about 40° C.) are obtainable in a planar structure owing to the thermal vias 30, 54 (thermally conductive, for example with thermal conductivity equal to hundreds of W·m⁻¹·K⁻¹, e.g., about 400 W·m⁻¹·K⁻¹) immersed in the thermoplastic layers 20, 52 (thermally insulating, for example with thermal conductivity lower than a few W·m⁻¹·K⁻¹, e.g., about 0.8 W·m⁻¹·K⁻¹) which have a thickness along the Z axis suitably sized to prevent the heat exchange therethrough between the thermal source 12 and the thermoelectric cell 100 in order to guarantee the desired temperature gradient through the thermoelectric microstructures 110N and 110P (e.g., thickness equal to a few μm or tens of e.g., about 10 μm).

Finally, it is clear that modifications and variations may be made to the disclosure described and illustrated herein without thereby departing from the scope of the present disclosure. For example, the different embodiments described may be combined with each other to provide further solutions.

Furthermore, the thermoelectric cell 100 may comprise only one thermoelectric element 110.

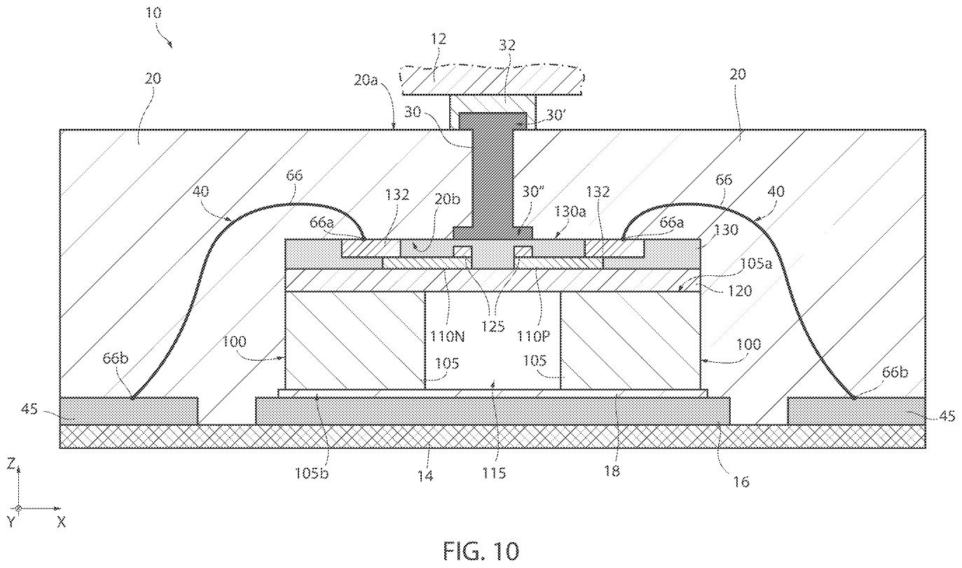

Furthermore, as shown in the embodiment of the generator 10 of FIG. 10, the electrical connection structures 40 may each comprise a respective conductive wire 66 of electrically conductive material (e.g., metal such as gold or copper) and having a first end 66a and a second end 66b opposite to each other along a main extension direction of the conductive wire 66. In each conductive wire 66, the first end 66a is coupled to the respective electrically conductive terminal 132 and the second end 66b is coupled to the respective lead 45 so that it electrically connects the electrically conductive terminals 132 to the respective leads 45.

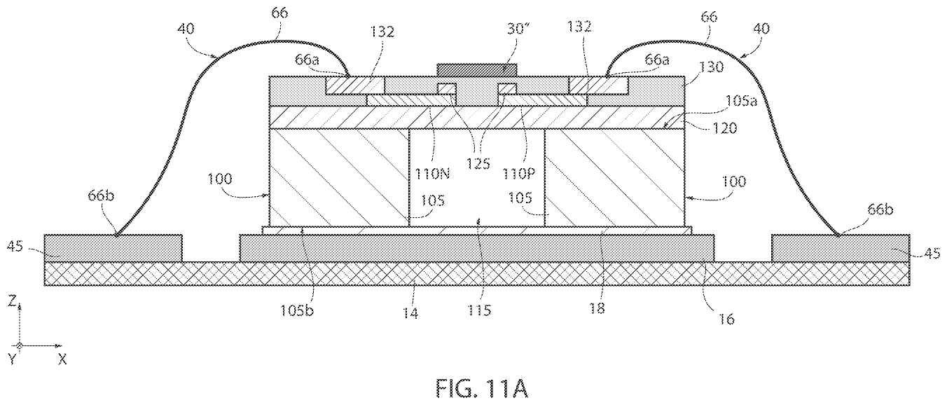

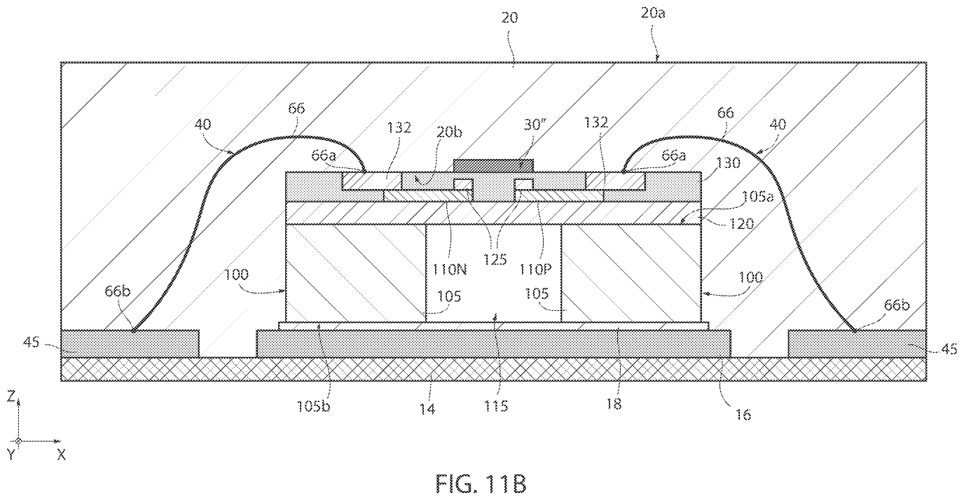

FIGS. 11A-11B show respective steps of the manufacturing process of the generator 10 of FIG. 10.

Initially and in a manner not discussed again, the thermoelectric cell 100 is provided as described with reference to FIGS. 5A-5H.

Subsequently, with reference to FIG. 11A, the thermoelectric cell 100 is fixed to the die pad 16 through the adhesive layer 18. Furthermore, the die pad 16 and the leads 45 are fixed to the heat sink 14, for example by known die attach techniques. Furthermore, the conductive wires 66 are fixed to the respective electrically conductive terminals 132 and to the respective leads 45, by per se known wire bonding techniques.

Subsequently, with reference to FIG. 11B, the first thermoplastic layer 20 is formed on the thermoelectric cell 100 and on the leads 45 so that it surrounds the conductive wires 66 to thermally insulate them from the external environment. The first thermoplastic layer 20 is formed by injection molding as previously described with reference to FIG. 6A.

Then manufacturing steps, similar to those described in FIGS. 6B-6D, follow to form the first thermal via 30 through the first thermoplastic layer 20, at the end of which the generator of FIG. 10 is obtained.

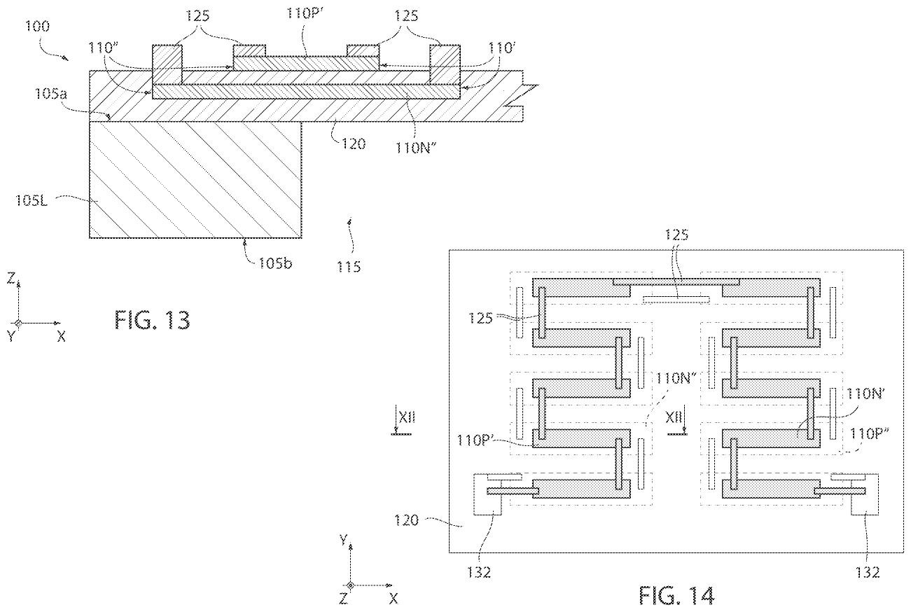

The thermoelectric cell 100 may also comprise thermoelectric elements 110 which are vertically superimposed on each other along the Z axis. In particular, the serpentine arrangement of the thermoelectric microstructures 110N and 110P may be repeated on more levels (i.e., at different heights with respect to the substrate 105) along the Z axis, as shown in FIGS. 13 and 14. This allows the total potential difference between the electrically conductive terminals 132 to be increased, with the same heat received by the thermal source 12 and surface of the thermoelectric cell in the XY plane.

By way of example, FIGS. 13 and 14 show the thermoelectric cell 100 with two superimposed levels of thermoelectric microstructures 110N and 110P; however, similar considerations apply to the case of more than two superimposed levels of thermoelectric microstructures 110N and 110P. In detail, FIG. 13 shows a portion of the thermoelectric cell 10 corresponding to the part comprising the first portion 105L of the substrate 105 and part of the cavity 115 (in other words, only the left half of the thermoelectric cell 100 is shown, while the right half comprising the second portion 105R of the substrate 105 is not shown for simplicity of description), in a section taken along section line XII-XII shown in FIG. 14. On the other hand, FIG. 14 is a top view, parallel to the XY plane, of the thermoelectric cell 100 of FIG. 13.

As shown in FIG. 14, the thermoelectric cell 100 may comprise first thermoelectric microstructures 110N′, 110P′ extending at a first height with respect to the substrate 105 (e.g., measured along the Z axis with respect to the first surface 105a of the substrate 105) and second thermoelectric microstructures 110N″, 110P″ extending at a second height with respect to the substrate 105 (e.g., also measured along the Z axis with respect to the first surface 105a of the substrate 105), where the second height is lower than the first height. By way of example, FIG. 13 shows a first P-type thermoelectric microstructure 110P′ and a second N-type thermoelectric microstructure 110N″. In particular, the second N-type thermoelectric microstructure 110N″ extends into the bottom electrically insulating layer 120 while the first P-type thermoelectric microstructure 110P′ extends on the bottom electrically insulating layer 120 so that it is vertically superimposed on the second N-type thermoelectric microstructure 110N″. The electrically conductive elements 125 of the second thermoelectric microstructures 110N″, 110P″ extend from the respective second thermoelectric microstructures 110N″, 110P″ up to protruding outside the bottom electrically insulating layer 120, so that it allows the electrical connection of the second thermoelectric microstructures 110N″, 110P″.

As shown in FIG. 14, the first thermoelectric microstructures 110N′, 110P′ are connected to each other through the electrically conductive elements 125 and have a first serpentine arrangement to each other similarly to what has been discussed with reference to FIG. 2; furthermore, the second thermoelectric microstructures 110N″, 110P″ (shown in dashed line in FIG. 14 as they are placed at a different height with respect to that of the first thermoelectric microstructures 110N′, 110P′) are connected to each other through respective electrically conductive elements 125 and have therebetween a second serpentine arrangement similarly to what has been discussed with reference to FIG. 2. The electrically conductive terminals 132 are placed at the ends of both serpentine arrangements. In other words, the first thermoelectric microstructures 110N′, 110P′ and the second thermoelectric microstructures 110N″, 110P″ are electrically placed in parallel with each other.

Alternatively, and in a manner not shown, the first thermoelectric microstructures 110N′, 110P′ and the second thermoelectric microstructures 110N″, 110P″ are electrically placed in series with each other. This is achieved, for each pair of thermoelectric microstructures superimposed on each other, by electrically contacting, through an electrically conductive element 125, one end of the first thermoelectric microstructure 110N′, 110P′ with the respective end of the second thermoelectric microstructure 110P″, 110N″ of opposite electrical conductivity (e.g., the first end 110′ of the first P-type thermoelectric microstructure 110P′ with the first end 110′ of the second N-type thermoelectric microstructure 110N″) and electrically contacting, through a further electrically conductive element 125, the other end of the first thermoelectric microstructure 110N′, 110P′ with the respective other end of the second thermoelectric microstructure 110P″, 110N″, of opposite electrical conductivity, of the pair of thermoelectric microstructures consecutive, in the serpentine arrangement, to the considered pair (e.g., the second end 100″ of the first P-type thermoelectric microstructure 110P′ with the second end 110″ of the second N-type thermoelectric microstructure 110N″ of the consecutive pair).

The thermoelectric cell 100 of FIGS. 13 and 14 is provided in the following manner. Firstly, the manufacturing steps described with reference to FIGS. 5A-5D are performed to form the second thermoelectric microstructures 110N″, 110P″. Subsequently, there are formed a further layer of insulating material such as oxide (e.g., silicon oxide), on the bottom electrically insulating layer 120 and on the second thermoelectric microstructures 110N″, 110P″, to increase the thickness of the bottom electrically insulating layer 120 and, in succession, a further thermoelectric material layer 204 on the bottom electrically insulating layer 120 of increased type. After that the steps of FIGS. 5B-5D are repeated to form the first thermoelectric microstructures 110N′, 110P′ on the bottom electrically insulating layer 120 of increased type. Finally, the steps of FIGS. 5E-5H are performed to obtain the thermoelectric cell 100 of FIG. 14 (in detail, in the step of FIG. 5F the electrically conductive elements 125 of both the first thermoelectric microstructures 110N′, 110P′ and the second thermoelectric microstructures 110N″, 110P″ are provided).

A MEMS thermoelectric generator (10) may be summarized as including at least one thermoelectric cell (100) including a substrate (105) of semiconductor material, having a first surface (105a) and a second surface (105b) opposite to each other along a first axis (Z), wherein a cavity (115) extends into the substrate (105) along the first axis (Z) from the second surface (105b) up to the first surface (105a); an electrically insulating layer (120, 130) of electrically insulating material, extending on the first surface (105a) of the substrate (105) and on the cavity (115); one or more thermoelectric elements (110) of thermoelectric material, each thermoelectric element (110) extending into the electrically insulating layer (120, 130), having a first end (110′) and a second end (110″) opposite to each other along a second axis (X) orthogonal to the first axis (Z) and being configured to convert a thermal drop between the first (110′) and the second (110″) ends into an electrical potential between the first (110′) and the second (110″) ends by Seebeck effect, wherein the first end (110′) of each thermoelectric element (110) is superimposed, along the first axis (Z), on the cavity (115) and the second end (110″) of each thermoelectric element (110) is superimposed, along the first axis (Z), on the substrate (105), the MEMS thermoelectric generator (10) further including a thermoplastic layer (20; 20, 48) extending on the electrically insulating layer (120, 130) and having a top surface (20a; 52a) and a bottom surface (20b) opposite to each other along the first axis (Z), the bottom surface (20b) of the electrically insulating layer (120, 130) facing the electrically insulating layer (120, 130), the thermoplastic layer (20; 20, 48) being of thermally insulating material and configured to be processed by laser direct structuring, LDS, technique; a heat sink (14) coupled to the thermoelectric cell and configured to exchange heat with the thermoelectric cell (100) which extends, along the first axis (Z), between the heat sink (14) and the thermoplastic layer (20; 20, 48); and a thermal via (30; 30, 50) of metal material, extending through the thermoplastic layer (20; 20, 48) from the top surface (20a; 52a) to the bottom surface (20b) of the thermoplastic layer (20; 20, 48) so that it is superimposed, along the first axis (Z), on the first end (110′) of each thermoelectric element (110), wherein the MEMS thermoelectric generator (10) is couplable to a thermal source (12) in such a way that the top surface (20a; 52a) of the thermoplastic layer (20; 20, 48) faces the thermal source (12) and the thermoelectric cell (100) exchanges heat, through the thermal via (30; 30, 50), with the thermal source (12) to generate the thermal drop between the first (110′) and the second (110″) ends of each thermoelectric element (110).

The thermoplastic layer (20; 20, 48) may be of thermoplastic polymeric material doped with organic-metal compounds configured to be chemically activated when radiated by a laser beam.

The thermoelectric cell (100) may include a first plurality of said thermoelectric elements (110), wherein the first plurality of thermoelectric elements (110) may include a respective first plurality of thermoelectric microstructures (110N′, 110P′) which are interconnected through electrically conductive elements (125) to form a first serpentine arrangement, wherein the first plurality of thermoelectric microstructures (110N′, 110P′) may include thermoelectric microstructures (110N′; 110P′) having a first type of electrical conductivity and thermoelectric microstructures (110P′; 110N′) having a second type of electrical conductivity opposite to the first type, the thermoelectric microstructures (110N′; 110P′) with the first type of electrical conductivity and the thermoelectric microstructures (110P′; 110N′) with the second type of electrical conductivity being alternated to each other along said first serpentine arrangement, and wherein the thermoelectric elements (110) and the electrically conductive elements (125) are buried in the electrically insulating layer (120, 130).

The thermoelectric cell (100) may further include a second plurality of said thermoelectric elements (110), wherein the second plurality of thermoelectric elements (110) may include a respective second plurality of thermoelectric microstructures (110N″, 110P″) which are interconnected through respective electrically conductive elements (125) to form a second serpentine arrangement, wherein the second plurality of thermoelectric microstructures (110N″, 110P″) may include respective thermoelectric microstructures (110N″; 110P″) having the first type of electrical conductivity and respective thermoelectric microstructures (110P″; 110N″) having the second type of electrical conductivity, the thermoelectric microstructures (110N″; 110P″) with the first type of electrical conductivity and the thermoelectric microstructures (110P″; 110N″) with the second type of electrical conductivity being alternated to each other along said second serpentine arrangement, wherein the first plurality of thermoelectric microstructures (110N′, 110P′) may be superimposed, along the first axis (Z), on the second plurality of thermoelectric microstructures (110N″, 110P″), and wherein the thermoelectric microstructures (110N′, 110P′) of the first plurality and the second plurality may be electrically arranged to each other: in series, the first and the second serpentine arrangements coinciding; or in parallel.

The thermoelectric cell (100) may further include electrically conductive terminals (132) placed at the ends of the first serpentine arrangement, in electrical contact with the thermoelectric elements (110), the MEMS thermoelectric generator also may include for each electrically conductive terminal (132), a respective lead (45) extending, laterally to the thermoelectric cell (100), on the heat sink (14) so that it is electrically insulated with respect to the heat sink (14) or on a PCB (64) fixed to the heat sink (14), the thermoplastic layer (20; 20, 48) also extending on the leads (45); and for each electrically conductive terminal (132), a respective electrical connection structure (40) of metal material, which extends at least partially into the thermoplastic layer (20; 20, 48) and which electrically couples the respective electrically conductive terminal (132) with the respective lead (45).

The thermoplastic layer (20) may be formed by a first thermoplastic layer (20) having said top surface (20a) and said bottom surface (20b), wherein the thermal via (30) may be formed by a first thermal via (30) having a first end (30′) and a second end (30″) opposite to each other along the first axis (Z), the first end (30′) of the first thermal via (30) facing the top surface (20a) of the thermoplastic layer (20) and the second end (30″) of the first thermal via (30) being in contact with the electrically insulating layer (120, 130) so that it may be superimposed, along the first axis (Z), on the first end (110′) of each thermoelectric element (110), wherein each electrical connection structure (40) may include a first electrical via (41), a second electrical via (42) and an electrical connection portion (43) which joins the first (41) and the second (42) electrical vias, wherein the first electrical via (41) may extend, laterally to the first thermal via (30), through the first thermoplastic layer (20) from the top surface (20a) of the thermoplastic layer (20) to the thermoelectric cell (100) so that it is in electrical contact with the respective electrically conductive terminal (132), wherein the second electrical via (42) may extend, laterally to the first electrical via (41), through the first thermoplastic layer (20) from the top surface (20a) of the thermoplastic layer (20) to the respective lead (45) so that it is in electrical contact with the respective lead (45), wherein the electrical connection portion (43) may extend on the top surface (20a) of the thermoplastic layer (20) between the first (41) and the second (42) electrical vias so that it electrically contacts each other, and wherein an insulation layer (44), of insulating material, may extend on the electrical connection portion (43).

The thermoplastic layer (20, 48) may be formed by a first thermoplastic layer (20) and by a second thermoplastic layer (48) extending on the first thermoplastic layer (20) and integral with the first thermoplastic layer (20), the first thermoplastic layer (20) defining said bottom surface (20b) of the thermoplastic layer (20, 48) and the second thermoplastic layer (48) defining said top surface (52a) and, wherein the thermal via (30, 50) may be formed by a first thermal via (30) and by a second thermal via (50) extending on the first thermal via (30) and integral with the first thermal via (30), the first thermal via (30) extending through the first thermoplastic layer (20) and the second thermal via (50) extending through the second thermoplastic layer (48), the thermal via (30, 50) having a first end (50′) and a second end (30″) opposite to each other along the first axis (Z), the first end (50′) of the thermal via (30, 50) being part of the second thermal via (50) and facing the top surface (52a) of the thermoplastic layer (20, 48) and the second end (30″) of the thermal via (30, 50) being part of the first thermal via (30) and being in contact with the electrically insulating layer (120, 130) so that it is superimposed, along the first axis (Z), on the first end (110′) of each thermoelectric element (110), wherein each electrical connection structure (40) may include a first electrical via (41), a second electrical via (42) and an electrical connection via (43) which may be interposed, along the first axis (Z), between the first (20) and the second (48) thermoplastic layers and which joins the first (41) and the second (42) electrical vias, wherein the first electrical via (41) may extend, laterally to the first thermal via (30), through the first thermoplastic layer (20) from the electrical connection portion (43) to the thermoelectric cell (100) so that it is in electrical contact with the respective electrically conductive terminal (132), wherein the second electrical via (42) may extend, laterally to the first electrical via (41), through the first thermoplastic layer (20) from the electrical connection portion (43) to the respective lead (45) so that it is in electrical contact with the respective lead (45), and wherein the electrical connection portion (43) may extend, along the second axis (X), between the first (41) and the second (42) electrical vias so that it electrically contacts each other.

Each electrical connection structure (40) may include a respective conductive wire (66) of metal material, extending into the thermoplastic layer (20) and having a first end (66a) and a second end (66b) opposite to each other, the first end (66a) of the conductive wire (66) being fixed to the respective electrically conductive terminal (132) and the second end (66b) of the conductive wire (66) being fixed to the respective lead (45).

The one or more thermoelectric elements (110) may be of polysilicon or polysilicon-germanium.

A manufacturing process of a MEMS thermoelectric generator (10), may be summarized as including the steps of forming, on a first surface (105a) of a substrate (105) of semiconductor material, an electrically insulating layer (120, 130) of electrically insulating material, the substrate (105) also having a second surface (105b) opposite to the first surface (105a) along a first axis (Z), wherein one or more thermoelectric elements (110) of thermoelectric material extend into the electrically insulating layer (120, 130), each thermoelectric element (110) having a first end (110′) and a second end (110″) opposite to each other along a second axis (X) orthogonal to the first axis (Z) and being configured to convert a thermal drop between the first (110′) and the second (110″) ends into an electric potential between the first (110′) and the second (110″) ends by Seebeck effect; and forming, in the substrate (105), a cavity (115) which extends from the second surface (105b) of the substrate (105) up to the first surface (105a) of the substrate (105), wherein the first end (110′) of each thermoelectric element (110) is superimposed, along the first axis (Z), on the cavity (115) and the second end (110″) of each thermoelectric element (110) is superimposed, along the first axis (Z), on the substrate (105), and wherein the substrate (105), the electrically insulating layer (120, 130) and the one or more thermoelectric elements (110) define a thermoelectric cell (100) of the MEMS thermoelectric generator (10), the manufacturing process further including the steps of coupling the thermoelectric cell (100) to a heat sink (14) configured to exchange heat with the thermoelectric cell (100), the heat sink (14) facing the second surface (105b) of the substrate (105); forming, on the electrically insulating layer (120, 130) a thermoplastic layer (20; 20, 48) having a top surface (20a; 52a) and a bottom surface (20b) opposite to each other along the first axis (Z), the bottom surface (20b) of the electrically insulating layer (120, 130) facing the electrically insulating layer (120, 130), the thermoplastic layer (20; 20, 48) being of thermally insulating material and configured to be processed by laser direct structuring, LDS, technique; and forming, in the thermoplastic layer (20; 48), a thermal via (30; 30, 50) of metal material, which extends from the top surface (20a; 52a) to the bottom surface (20b) of the thermoplastic layer (20; 20, 48) so that it is superimposed, along the first axis (Z), on the first end (110′) of each thermoelectric element (110), wherein the MEMS thermoelectric generator (10) is couplable to a thermal source (12) in such a way that the top surface (20a; 52a) of the thermoplastic layer (20; 20, 48) faces the thermal source (12) and the thermoelectric cell (100) exchanges heat, through the thermal via (30; 30, 50), with the thermal source (12) to generate the thermal drop between the first (110′) and the second (110″) ends of each thermoelectric element (110).

The step of forming the electrically insulating layer (120, 130) may include: a. forming, on the first surface (105a) of the substrate (105), a bottom electrically insulating layer (120) of electrically insulating material; b. forming, on the bottom electrically insulating layer (120), a thermoelectric material layer (204) of thermoelectric material; c. forming, in the thermoelectric material layer (204), at least one first doped portion (206N) by doping at least one respective first exposed region (204N) of the thermoelectric material layer (204) with doping species having a first type of electrical conductivity; d. removing the thermoelectric material layer (204) leaving the at least one first doped portion (206N) on the bottom electrically insulating layer (120), each first doped portion (206N) forming a respective thermoelectric element (110N) with the first type of conductivity of said thermoelectric elements (110); e. forming, on the bottom electrically insulating layer (120) and on each thermoelectric element (110), a first insulating layer (129) of electrically insulating material which includes a top electrically insulating layer (130), the bottom electrically insulating layer (120) and the top electrically insulating layer (130) defining said electrically insulating layer (120, 130).

The step of forming the electrically insulating layer (120, 130) may further include between step c. and d., forming in the thermoelectric material layer (204) at least one second doped portion (206P) by doping, with further doping species having a second type of electrical conductivity opposite to the first type, at least one second exposed region (204P) of the thermoelectric material layer (204), lateral to the at least one first exposed region (204N); during step d., removing the thermoelectric material layer (204) leaving both the at least one first doped portion (206N) and the at least one second doped portion (206P) on the bottom electrically insulating layer (120), each second doped portion (206P) forming a respective thermoelectric element (110P) with the second type of conductivity of said thermoelectric elements (110); after step e., forming, through the first insulating layer (129), at least one electrically conductive element (125) of conductive material, which electrically contacts a respective thermoelectric element (110N) with the first type of conductivity and a respective thermoelectric element (110P) with the second type of conductivity to interconnect them; and forming, on the first insulating layer (129) and on the at least one electrically conductive element (125), one or more second insulating layers of electrically insulating material which define, with the first insulating layer (129), said top electrically insulating layer (130).

The step of forming the cavity (115) in the substrate (105) may include temporarily coupling the thermoelectric cell (100) to a transport wafer (216), the transport wafer (216) facing the electrically insulating layer (120, 130) of the thermoelectric cell (100); performing an etching at a cavity region (220) of the second surface (105b) of the substrate (105) to form the cavity (115), the cavity region (220) being aligned along the first axis (Z) with the first end (110′) of each thermoelectric element (110); and decoupling the thermoelectric cell (100) and the transport wafer (216) from each other.

The step of forming a thermoplastic layer (20; 20, 48) may include forming a first thermoplastic layer (20) on the electrically insulating layer (120, 130) by injection molding, the first thermoplastic layer (20) being the thermoplastic layer (20) or being part of the thermoplastic layer (20, 48).

The step of forming the thermal via (30; 30, 50) in the thermoplastic layer (20; 20, 48) may include forming a first trench (140) in the first thermoplastic layer (20), from a top surface (20a) up to a bottom surface (20b) of the first thermoplastic layer (20), the first trench (140) being formed by radiating through laser with LDS technique a first trench region of the top surface (20a) of the first thermoplastic layer (20) to selectively remove a corresponding part of the first thermoplastic layer (20), the first trench region being superimposed, along the first axis (Z), on the cavity (115); and performing a metal deposition in the first trench (140) to form a first thermal via (30), the first thermal via (30) being the thermal via (30) or being part of the thermal via (30, 50).

The thermoelectric cell (100) may include a plurality of said thermoelectric elements (110) interconnected to form a serpentine arrangement, the manufacturing process may further include the steps of forming, in the electrically insulating layer (120, 130), electrically conductive terminals (132) placed at the ends of the serpentine arrangement and exposed by the electrically insulating layer (120, 130); for each electrically conductive terminal (132), forming a respective second trench (141) and a respective third trench (142) in the first thermoplastic layer (20), from the top surface (20a) up to the bottom surface (20b) of the first thermoplastic layer (20), the respective second (141) and third (142) trenches being arranged laterally to the first trench (140) and being formed by radiating through laser with LDS technique respective second and third trench regions of the top surface (20a) of the first thermoplastic layer (20) to selectively remove corresponding parts of the first thermoplastic layer (20), the respective second and third trench regions being superimposed, along the first axis (Z), on the respective electrically conductive terminal (132) and, respectively, on a respective lead (45) extending on the heat sink (14) laterally to the thermoelectric cell (100), the first thermoplastic layer (20) also being formed on the respective lead (45); for each electrically conductive terminal (132), chemically activating, by laser radiation with LDS technique, a respective activated region (143) of the top surface (20a) of the first thermoplastic layer (20), which extends between the respective second and third trench regions; and performing a metal deposition in the second (141) and third (142) trenches to form respective first (41) and second (42) electrical vias, and on the activated regions (143) to form respective electrical connection portions (43) interposed along the second axis (X) between the respective first (41) and second (42) electrical vias, the respective first (41) and second (42) electrical vias and the respective electrical connection portions (43) forming together respective electrical connection structures (40) which electrically connect the respective electrically conductive terminals (132) and the respective leads (45) to each other.

The manufacturing process may further include the step of forming an insulation layer (44) of insulating material on each of the electrical connection structures (40), or also may include the steps of forming by injection molding a second thermoplastic layer (48) on the first thermoplastic layer (20), on the electrical connection structures (40) and on the first thermal via (30), the second thermoplastic layer (48) forming with the first thermoplastic layer (20) said thermoplastic layer (20, 48); and forming, in the second thermoplastic layer (48), a second thermal via (50) of metal material, superimposed, along the first axis (Z), on the first thermal via (50), the first (30) and the second (50) thermal vias forming said thermal via (30, 50).

The thermoelectric cell (100) may include a plurality of said thermoelectric elements (110) interconnected to form a serpentine arrangement, the manufacturing process may further include, before forming the thermoplastic layer (20) on the electrically insulating layer (120, 130), the steps of forming, in the electrically insulating layer (120, 130), electrically conductive terminals (132) placed at the ends of the serpentine arrangement and exposed by the electrically insulating layer (120, 130); fixing to each electrically conductive terminal (132) a first end (66a) of a respective conductive wire (66), and to a respective lead (45) a second end (66a) of said respective conductive wire (66), the first (66a) and the second (66b) ends of each conductive wire (66) being opposite to each other, each lead (45) extending on the heat sink (14) laterally to the thermoelectric cell (100); and forming the thermoplastic layer (20) also on the conductive wires (66).

A heating system (500) may be summarized as including a heating apparatus (502) and a control apparatus (504) including a MEMS thermoelectric generator (10), according to any of claims 1-9, coupled to the heating apparatus (502) to exchange heat with the heating apparatus (502), the heating apparatus (502) being said thermal source (12).

The various embodiments described above can be combined to provide further embodiments. Aspects of the embodiments can be modified, if necessary to employ concepts of the various patents, applications and publications to provide yet further embodiments.

These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A Micro Electro-Mechanical Systems (MEMS) thermoelectric generator comprising:
at least one thermoelectric cell including:
a substrate of semiconductor material having a cavity between a first surface of the substrate and a second surface of the substrate opposite to each other along a first direction;
an electrically insulating layer on the first surface of the substrate and over the cavity; and
one or more thermoelectric elements in the electrically insulating layer, each thermoelectric element of the one or more thermoelectric elements having a first end and a second end opposite to each other along a second direction transverse to the first direction and being configured to convert a thermal drop between the first and the second ends into an electrical potential between the first and the second ends by Seebeck effect, the first end of each thermoelectric element over the cavity and the second end of each thermoelectric element over the substrate;
a thermoplastic layer extending on the at least one thermoelectric cell, the thermoplastic layer being of thermally insulating material and configured to be processed by laser direct structuring, LDS, technique;
a heat sink coupled to a first end of the at least one thermoelectric cell and configured to exchange heat with the thermoelectric cell, the heat sink opposite a first surface of the thermoplastic layer; and
a thermal via of metal material extending through the thermoplastic layer from the electrically insulating layer to the first surface of the thermoplastic layer, the thermal via over the first end of each thermoelectric element;
wherein the MEMS thermoelectric generator is couplable to a thermal source with the first surface of the thermoplastic layer facing the thermal source and the at least one thermoelectric cell exchanging heat, through the thermal via, with the thermal source to generate the thermal drop between the first and the second ends of each thermoelectric element.

2. The MEMS thermoelectric generator according to claim 1, wherein the at least one thermoelectric cell includes a first plurality of said thermoelectric elements
wherein the first plurality of thermoelectric elements includes a respective first plurality of thermoelectric microstructures interconnected through electrically conductive elements to form a first serpentine arrangement,
wherein the first plurality of thermoelectric microstructures includes first thermoelectric microstructures having a first type of electrical conductivity and second thermoelectric microstructures having a second type of electrical conductivity different from the first type, the first thermoelectric microstructures with the first type of electrical conductivity and the second thermoelectric microstructures with the second type of electrical conductivity being alternated to each other along said first serpentine arrangement, and
wherein the thermoelectric elements and the electrically conductive elements are buried in the electrically insulating layer.

3. The MEMS thermoelectric generator according to claim 2, wherein the thermoelectric cell includes a second plurality of said thermoelectric elements,
wherein the second plurality of thermoelectric elements includes a respective second plurality of thermoelectric microstructures interconnected through respective electrically conductive elements to form a second serpentine arrangement,
wherein the second plurality of thermoelectric microstructures includes respective first thermoelectric microstructures having the first type of electrical conductivity and respective second thermoelectric microstructures having the second type of electrical conductivity, the first thermoelectric microstructures and the second thermoelectric microstructures being alternated to each other along said second serpentine arrangement,
wherein the first plurality of thermoelectric microstructures is superimposed, along the first direction, on the second plurality of thermoelectric microstructures, and
wherein the first and second plurality of thermoelectric microstructures are electrically arranged to each other, in series, the first and the second serpentine arrangements coinciding or in parallel.

4. The MEMS thermoelectric generator according to claim 2, wherein the thermoelectric cell includes electrically conductive terminals placed at ends of the first serpentine arrangement, in electrical contact with the thermoelectric elements each electrically conductive terminal, electrically coupled to a respective lead via a respective electrical connection structure, the lead being electrically insulated from the heat sink, the thermoplastic layer extending on the leads, and the respective electrical connection structure being of metal material extends at least partially into the thermoplastic layer.

5. The MEMS thermoelectric generator according to claim 4, wherein the thermoplastic layer includes a first thermoplastic layer having said first surface;
wherein the thermal via includes a first thermal via having a first end and a second end opposite to each other along the first direction, the first end of the first thermal via facing the first surface of the thermoplastic layer and the second end of the first thermal via being in contact with the electrically insulating layer so that it is superimposed, along the first direction, on the first end of each thermoelectric element;
wherein each electrical connection structure comprises a first electrical via, a second electrical via and an electrical connection portion which joins the first and the second electrical vias;
wherein the first electrical via extends from the first surface of the thermoplastic layer through the first thermoplastic layer to the thermoelectric cell so that it is in electrical contact with the respective electrically conductive terminal;
wherein the second electrical via extends from the first surface of thermoplastic layer through the first thermoplastic layer to the respective lead so that it is in electrical contact with the respective lead;
wherein the electrical connection portion extends on the first surface of the thermoplastic layer between the first and the second electrical vias so that it electrically contacts each other; and
wherein an insulation layer, of insulating material, extends on the electrical connection portion.

6. The MEMS thermoelectric generator according to claim 4, wherein the thermoplastic layer includes a first thermoplastic layer and a second thermoplastic layer extending on the first thermoplastic layer and integral with the first thermoplastic layer, the second thermoplastic layer defining said first surface of the thermoplastic layer and,
wherein the thermal via includes a first thermal via and a second thermal via extending on the first thermal via and integral with the first thermal via, the first thermal via extending through the first thermoplastic layer and the second thermal via extending through the second thermoplastic layer, the thermal via having a first end and a second end opposite to each other along the first direction, the first end of the thermal via being part of the second thermal via and facing the first surface of the thermoplastic layer and the second end of the thermal via being part of the first thermal via and being in contact with the electrically insulating layer so that it is superimposed, along the first direction, on the first end of each thermoelectric element;
wherein each electrical connection structure comprises a first electrical via, a second electrical via and an electrical connection via which is interposed, along the first direction, between the first and the second thermoplastic layers and which joins the first and the second electrical vias;
wherein the first electrical via extends through the first thermoplastic layer from the electrical connection portion to the thermoelectric cell so that it is in electrical contact with the respective electrically conductive terminal;
wherein the second electrical via extends through the first thermoplastic layer from the electrical connection portion to the respective lead so that it is in electrical contact with the respective lead; and
wherein the electrical connection portion extends along the second direction between the first and the second electrical vias so that it electrically contacts each other.

7. The MEMS thermoelectric generator according to claim 4, wherein each electrical connection structure includes a respective conductive wire of metal material, extending into the thermoplastic layer and having a first end and a second end opposite to each other, the first end of the conductive wire being fixed to the respective electrically conductive terminal and the second end of the conductive wire being fixed to the respective lead.

8. A manufacturing process of a MEMS thermoelectric generator, the process comprising:
forming, on a first surface of a substrate of semiconductor material, an electrically insulating layer of electrically insulating material, the substrate having a second surface opposite to the first surface along a first direction, one or more thermoelectric elements of thermoelectric material in the electrically insulating layer, each thermoelectric element having a first end and a second end opposite to each other along a second direction transverse to the first direction and being configured to convert a thermal drop between the first and the second ends into an electric potential between the first and the second ends by Seebeck effect;
forming, in the substrate, a cavity which extends from the second surface of the substrate to the first surface of the substrate, the first end of each thermoelectric element is superimposed, along the first direction, on the cavity and the second end of each thermoelectric element is superimposed, along the first direction, on the substrate;
wherein the substrate, the electrically insulating layer and the one or more thermoelectric elements define a thermoelectric cell of the MEMS thermoelectric generator;
coupling the thermoelectric cell to a heat sink configured to exchange heat with the thermoelectric cell, the heat sink facing the second surface of the substrate;
forming, on the electrically insulating layer a first thermoplastic layer having a first surface and a second surface opposite to each other along the first direction, the second surface of the electrically insulating layer facing the electrically insulating layer, the first thermoplastic layer being of thermally insulating material and configured to be processed by laser direct structuring, LDS, technique; and
forming, in the first thermoplastic layer, a first thermal via of metal material, which extends from the first surface to the second surface of the first thermoplastic layer so that it is superimposed, along the first direction, on the first end of each thermoelectric element;
wherein the MEMS thermoelectric generator is couplable to a thermal source in such a way that the first surface of the first thermoplastic layer faces the thermal source and the thermoelectric cell exchanges heat, through the first thermal via, with the thermal source to generate the thermal drop between the first and the second ends of each thermoelectric element.

9. The manufacturing process according to claim 8, wherein forming the electrically insulating layer comprises:
forming, on the first surface of the substrate, a second electrically insulating layer of electrically insulating material;
forming, on the second electrically insulating layer, a thermoelectric material layer of thermoelectric material;
forming, in the thermoelectric material layer, at least one first doped portion by doping at least one respective first exposed region of the thermoelectric material layer with doping species having a first type of electrical conductivity;
removing the thermoelectric material layer leaving the at least one first doped portion on the second electrically insulating layer, each first doped portion forming a respective thermoelectric element with the first type of conductivity of said thermoelectric elements; and
forming, on the second electrically insulating layer and on each thermoelectric element, a first insulating layer of electrically insulating material which is comprised in a first electrically insulating layer, the second electrically insulating layer and the first electrically insulating layer defining said electrically insulating layer.

10. The manufacturing process according to claim 9, wherein forming the electrically insulating layer comprises:
after forming the at least one first doped portion and before removing the thermoelectric material layer, forming in the thermoelectric material layer at least one second doped portion by doping, with further doping species having a second type of electrical conductivity opposite to the first type, at least one second exposed region of the thermoelectric material layer, spaced from the at least one first exposed region;
wherein removing the thermoelectric material layer includes leaving both the at least one first doped portion and the at least one second doped portion on the second electrically insulating layer, each second doped portion forming a respective thermoelectric element with the second type of conductivity of said thermoelectric elements;
after forming the first insulating layer, forming, through the first insulating layer, at least one electrically conductive element of conductive material, which electrically contacts a respective thermoelectric element with the first type of conductivity and a respective thermoelectric element with the second type of conductivity to interconnect them; and
forming, on the first insulating layer and on the at least one electrically conductive element, one or more second insulating layers of electrically insulating material, the first insulating layer including the first electrically insulating layer and the one or more second insulating layers of electrically insulating material.

11. The manufacturing process according to claim 8, wherein forming the cavity in the substrate includes:
temporarily coupling the thermoelectric cell to a transport wafer, the transport wafer facing the electrically insulating layer of the thermoelectric cell;
performing an etching at a cavity region of the second surface of the substrate to form the cavity, the cavity region being aligned along the first direction with the first end of each thermoelectric element; and
decoupling the thermoelectric cell and the transport wafer from each other.

12. The manufacturing process according to claim 8, wherein forming, on the electrically insulating layer, the first thermoplastic layer is carried out by injection molding.

13. The manufacturing process according to claim 12, wherein forming, in the first thermoplastic layer, the first thermal via includes:
forming a first trench in the first thermoplastic layer, from the first surface to the second surface of the first thermoplastic layer, the first trench being formed by radiating through laser with LDS technique a first trench region of the first surface of the first thermoplastic layer to selectively remove a corresponding part of the first thermoplastic layer, the first trench region being superimposed, along the first direction, on the cavity; and
performing a metal deposition in the first trench to form the first thermal via.

14. The manufacturing process according to claim 13, wherein the thermoelectric cell includes a plurality of said thermoelectric elements interconnected to form a serpentine arrangement,
the manufacturing process comprising:
forming, in the electrically insulating layer, electrically conductive terminals placed at the ends of the serpentine arrangement and exposed by the electrically insulating layer;
for each electrically conductive terminal, forming a respective second trench and a respective third trench in the first thermoplastic layer, from the first surface up to the second surface of the first thermoplastic layer, the respective second and third trenches being arranged laterally to the first trench and being formed by radiating through laser with LDS technique respective second and third trench regions of the first surface of the first thermoplastic layer to selectively remove corresponding parts of the first thermoplastic layer, the respective second and third trench regions being superimposed, along the first direction, on the respective electrically conductive terminal and, respectively, on a respective lead extending on the heat sink laterally to the thermoelectric cell, the first thermoplastic layer also being formed on the respective lead;
for each electrically conductive terminal, chemically activating, by laser radiation with LDS technique, a respective activated region of the first surface of the first thermoplastic layer, which extends between the respective second and third trench regions; and
performing a metal deposition in the second and third trenches to form respective first and second electrical vias, and on the activated regions to form respective electrical connection portions interposed along the second direction between the respective first and second electrical vias, the respective first and second electrical vias and the respective electrical connection portions forming together respective electrical connection structures which electrically connect the respective electrically conductive terminals and the respective leads to each other.

15. The manufacturing process according to claim 14, comprising forming an insulation layer of insulating material on each of the electrical connection structures.

16. The manufacturing process according to claim 15, comprising
forming by injection molding a second thermoplastic layer on the first thermoplastic layer, on the electrical connection structures and on the first thermal via, the second thermoplastic layer forming with the first thermoplastic layer said thermoplastic layer; and
forming, in the second thermoplastic layer, a second thermal via of metal material, superimposed, along the first direction, on the first thermal via.

17. The manufacturing process according to claim 8, wherein the thermoelectric cell comprises a plurality of said thermoelectric elements interconnected to form a serpentine arrangement,
the manufacturing process comprising, before forming the thermoplastic layer on the electrically insulating layer:
forming, in the electrically insulating layer, electrically conductive terminals placed at the ends of the serpentine arrangement and exposed by the electrically insulating layer;
fixing to each electrically conductive terminal a first end of a respective conductive wire, and to a respective lead a second end of said respective conductive wire, the first and the second ends of each conductive wire being opposite to each other, each lead extending on the heat sink laterally to the thermoelectric cell; and
forming the thermoplastic layer also on the conductive wires.

18. A device comprising:
a heat sink;
a thermoelectric cell having a first surface coupled to the heat sink, the thermoelectric cell including:
a first substrate portion;
a second substrate portion spaced from the first substrate portion;
an electrically insulating layer extending from the first substrate portion to the second substrate portion, the electrically insulating layer having a first surface opposite the first surface of the thermoelectric cell;
a central cavity between the first and second substrate portions, the electrically insulating layer extending over the central cavity; and
a plurality of thermoelectric elements in the electrically insulating layer;
a thermoplastic layer on the thermoelectric cell, the thermoplastic layer having a first surface opposite the heat sink; and
a thermal via extending from the first surface of the thermoplastic layer to the first surface of the electrically insulating layer through the thermoplastic layer.

19. The device according to claim 18, wherein each of the plurality of thermoelectric elements includes a first end opposite a second end, the first end being over the central cavity and the second end being over the first or second substrate portion.

20. The device according to claim 19, wherein the thermal via includes a first end opposite a second end, the first end being on the first surface of the thermoplastic layer, and the second end contacting the thermoelectric cell over the first ends of the plurality of thermoelectric elements.
